(19) United States
(12) Patent Application Publication
(10) Pub. No.: US 2015/0137902 A1
(43) Pub. Date: May 21, 2015

(54) RESONATOR ELEMENT, RESONATOR, OSCILLATOR, ELECTRONIC APPARATUS, AND MOBILE OBJECT

(71) Applicant: SEIKO EPSON CORPORATION, Tokyo (JP)

(72) Inventor: Akinori YAMADA, Ina-shi (JP)

(21) Appl. No.: 14/541,916

(22) Filed: Nov. 14, 2014

(30) Foreign Application Priority Data
Nov. 16, 2013 (JP) 2013-237478

(51) Int. Cl. H03H 9/215; H03B 5/32

(52) U.S. Cl. CPC H03H 9/215; H03B 5/32
USPC 331/156; 310/370

(57) ABSTRACT

Grooves are provided on two main surfaces of a vibration arm. When a thickness of the vibration arm is T, a width of the main surface between an outer edge of the vibration arm and the groove in a plan view along a direction orthogonal to the extending direction of the main surface is W, a sum of depths of the grooves is ta, and ta/T is η, a region that satisfies a relationship of 4.236×10×η²−8.473×10×η+4.414×10 [μm]≦W [μm]≦−3.367×10×η²+7.112×10×η−2.352×10 [μm], and 0.75≦η<1.00 is present on at least a part of the vibration arm in the extending direction. When a length of the vibration arm in the extending direction is L, and a length of the weight section in the extending direction is H, a relationship of 0.012<H/L<0.30 is satisfied.

### CROSS REFERENCE

The entire disclose of Japanese Patent Application No. 2013-237478, filed Nov. 16, 2013, is expressly incorporated by reference herein.

### BACKGROUND

1. Technical Field

The present invention relates to a resonator element, a resonator, an oscillator, an electronic apparatus, and a mobile object.

2. Related Art

In the related art, a resonator element that uses a quartz crystal is known (for example, see JP-UM-A-2-32229). Such a resonator element is good in frequency-temperature characteristics, and thus is widely used as a reference frequency source or an emission source of various electronic apparatuses.

JP-UM-A-2-32229 discloses a resonator element that is of a tuning fork type and includes a proximal section and a pair of vibration arms that extend from the proximal section. In addition, on each of the vibration arms, a pair of grooves that opens on the top surface and the underside thereof is formed. Therefore, the vibration arms have a substantial H cross-sectional shape. The vibration arm has such a shape, thereby it is possible to decrease a reduction of a Q value due to a thermoelastic loss, and it is possible to exhibit good vibration characteristics. However, there have not been sufficient studies of a relationship between a shape (including a size) of the grooves and the thermoelastic loss while the reduction of the Q value due to the thermoelastic loss is sufficiently decreased.

### SUMMARY

An advantage of the some aspects of the invention is to provide a resonator element having good vibration characteristics in which a reduction of a Q value due to a thermoelastic loss is decreased, a resonator, an oscillator, an electronic apparatus, and a mobile object which include the resonator element.

The invention can be implemented as the following application examples.

### Application Example 1

A resonator element according to this application example includes: a proximal section; and a pair of vibration arms which extend from the proximal section in a plan view and in which grooves are provided on a first main surface and on a second main surface thereof which are on a front side and on a rear side of the vibration arms. Each vibration arm includes a weight section and an arm section that is disposed between the proximal section and the weight section in a plan view. When a thickness of the vibration arm is T, a width of the main surface between an outer edge of the vibration arm and the groove in a plan view along a direction orthogonal to the extending direction of the main surface is W, a sum of depths of the grooves is ta, and ta/T is η, a region that satisfies 4.236×10×η²−8.473×10×η+4.414×10 [μm]≦W [μm]≦−3.367×10×η²+7.112×10×η−2.352×10 [μm], and 0.75≦η<1.00 is at least apart of the vibration arm in the extending direction. When a length of the vibration arm along the extending direction is L, and a length of the weight section along the extending direction is H, a relationship of 0.012<H/L<0.30 is satisfied.

By satisfying such conditions, it is possible to further reduce a thermoelastic loss than in the related art, and therefore a resonator element is obtained, in which a high Q value is obtained and thus it is possible to exhibit good vibration characteristics.

In particular, a relationship of 0.012<H/L<0.30 is satisfied and thereby it is possible to reduce an increase of a CI value.

### Application Example 2

A resonator element according to this application example includes: a proximal section; and a pair of vibration arms which extend from the proximal section in a plan view and in which grooves are provided on a first main surface and on a second main surface thereof which are on a front side and on a rear side of the vibration arms. Each vibration arm includes a weight section and an arm section that is disposed between the proximal section and the weight section in a plan view. When a thickness of the vibration arm is T, a width of the main surface between an outer edge of the vibration arm and the groove in a plan view along a direction orthogonal to the extending direction of the main surface is W, a sum of depths of the grooves is ta, and ta/η is a region that satisfies 4.236×10×η²−8.473×10×η+4.414×10 [μm]≦W [μm]≦−3.367×10×η²+7.112×10×η−2.352×10 [μm], and 0.75≦η<1.00 is at least a part of the vibration arm in the extending direction. When a length of the vibration arm along the extending direction is L, and a length of the weight section in the extending direction is H, a relationship of 0.183≦H/L≦0.597 is satisfied.

By satisfying such conditions, it is possible to further reduce a thermoelastic loss than in the related art, and therefore a resonator element is obtained, in which a high Q value is obtained and thus it is possible to exhibit good vibration characteristics.

In particular, a relationship of 0.183≦H/L≦0.597 is satisfied and thereby it is possible to miniaturize the resonator element and to decrease degradation of vibration characteristics.

### Application Example 3

In the resonator element according to the application example described above, it is preferable that the thickness of the vibration arm is 110 μm to 150 μm.

According to this configuration, while a high Q value and a low CI value are maintained, it is possible to easily form a minute shape through wet etching.

### Application Example 4

In the resonator element according to the application example described above, it is preferable that the pair of vibration arms has a fundamental vibration mode to flexurally vibrate to a side opposite to each other in the orthogonal direction such that the pair of vibration arms repeats approaching and separating from each other alternately, and when a resonance frequency of the fundamental vibration mode is f0 and a resonance frequency of a vibration mode different from the fundamental vibration mode is f1, the following relationship be satisfied.

|f0−f1|/f0≧0.124

With this configuration, an occurrence of combination between the fundamental vibration mode and the vibration mode different from the fundamental vibration mode is likely to be low and thus it is possible to obtain a high Q value.

### Application Example 5

In the resonator element according to the application example described above, it is preferable that the groove has a bottom surface with a uniform depth.

With this configuration, it is possible to reduce the thermoelastic loss and to obtain a high Q value, compared to a resonator element including a groove having a bottom surface with a non-uniform depth.

### Application Example 6

In the resonator element according to the application example described above, it is preferable that the groove has a bottom surface with a non-uniform depth.

With this configuration, it is possible to achieve a resonator element that has a high rigidity and strength against an impact or the like, compared to a resonator element including a groove having a bottom surface with a uniform depth.

### Application Example 7

A resonator according to this application example includes: the resonator element according to the application example described above; and a package in which the resonator element is accommodated.

With this configuration, a resonator having a good reliability is obtained.

### Application Example 8

An oscillator according to this application example includes: the resonator element according to the application example described above; and an oscillation circuit that is connected electrically to the resonator element.

With this configuration, an oscillator having a good reliability is obtained.

### Application Example 9

An electronic apparatus according to this application example includes: the resonator element according to the application example described above.

With this configuration, an electronic apparatus having a good reliability is obtained.

### Application Example 10

A mobile object according to this application example includes: the resonator element according to the application example described above.

With this configuration, a mobile object having a good reliability is obtained.

### BRIEF DESCRIPTION OF THE DRAWINGS

The invention will be described with reference to the accompanying drawings, wherein like numbers reference like elements.

FIG. 1 is a plan view of a resonator according to the first embodiment of the invention.

FIG. 2 is a cross-sectional view taken along line A-A in FIG. 1.

FIG. 3 is a cross-sectional view (cross-sectional view taken along line B-B in FIG. 1) of a resonator element including the resonator illustrated in FIG. 1.

FIG. 4 is a cross-sectional view of a vibration arm for illustrating thermal conduction during flexural vibration.

FIG. 5 is a graph illustrating a relationship between a Q value and f/fm.

FIG. 6 is a cross-sectional view illustrating the vibration arm formed through wet etching.

FIG. 7 is a graph illustrating a relationship between W and Q_{TED}a.

FIG. 8 is a graph illustrating a relationship between η and W.

FIG. 9 is a graph illustrating a relationship between η and W.

FIG. 10 is a graph illustrating a relationship between η and W.

FIG. 11 is a graph illustrating a relationship between η and W.

FIG. 12 is a graph illustrating a relationship between η and W.

FIG. 13 is a graph illustrating a relationship between η and W.

FIGS. 14A to 14D are cross-sectional views for illustrating a manufacturing method of the resonator element illustrated in FIG. 1.

FIGS. 15A to 15C are cross-sectional views for illustrating a manufacturing method of the resonator element illustrated in FIG. 1.

FIGS. 16A and 16B are graphs illustrating a relationship between a hammer head occupancy ratio and a R1-lowered index.

FIG. 17 is a graph illustrating a relationship between H/L and a normalized value according to a second embodiment.

FIG. 18 is a graph illustrating a relationship between H/L and a high-performance index 1 according to the second embodiment.

FIG. 19 is a graph illustrating a relationship between Δf and a high-performance index 3 according to the third embodiment of the invention.

FIG. 20 is a cross-sectional view of the resonator element that includes the resonator according to the fourth embodiment of the invention.

FIG. 21 is a plan view of the resonator according to the fifth embodiment of the invention.

FIG. 22 is a cross-sectional view illustrating an embodiment of an oscillator according to the invention.

FIG. 23 is a perspective view illustrating a configuration of a mobile type (or notebook type) personal computer to which an electronic apparatus according to the invention is applied.

FIG. 24 is a perspective view illustrating a configuration of a mobile phone (including PHS) to which the electronic apparatus according to the invention is applied.

FIG. 25 is a perspective view illustrating a configuration of a digital still camera to which the electronic apparatus according to the invention is applied.

FIG. 26 is a perspective view illustrating a configuration of an automobile to which a mobile object according to the invention is applied.

### DESCRIPTION OF EXEMPLARY EMBODIMENTS

Hereinafter, a resonator element, a resonator, an oscillator, an electronic apparatus, and a mobile object according to the invention will be described in detail in accordance with an exemplary embodiment illustrated in the accompanying drawings.

### 1. Resonator

First, the resonator according to the invention is described.

### First Embodiment

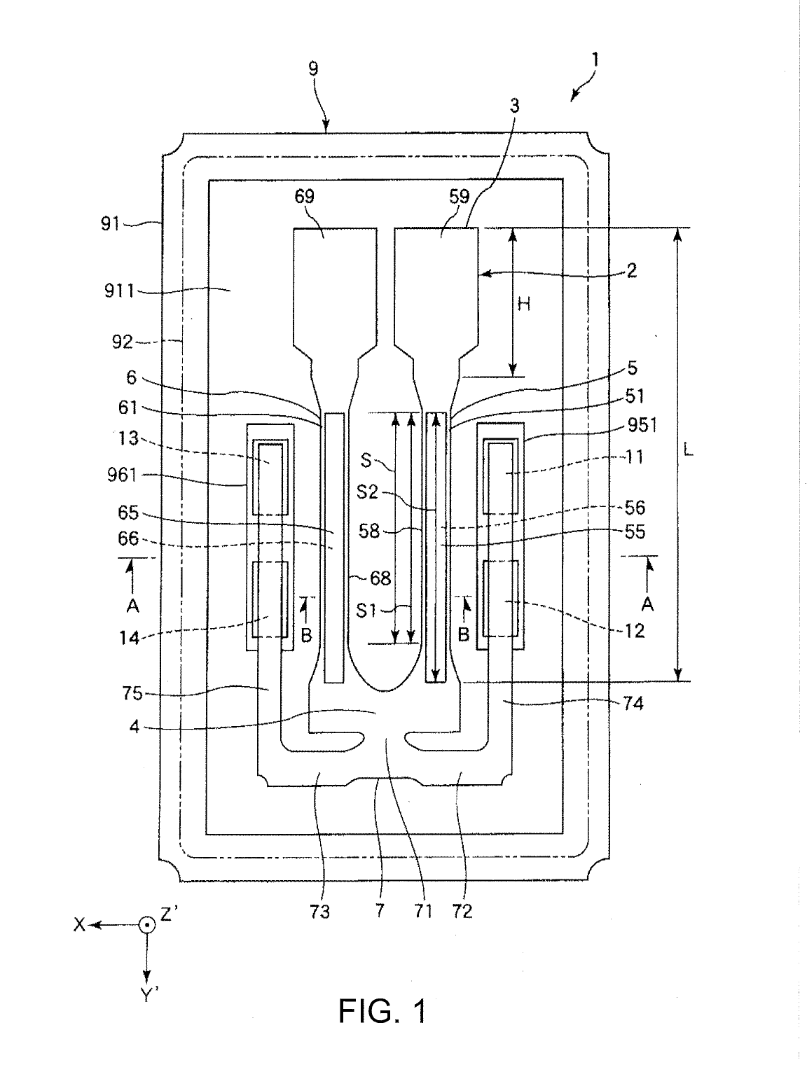

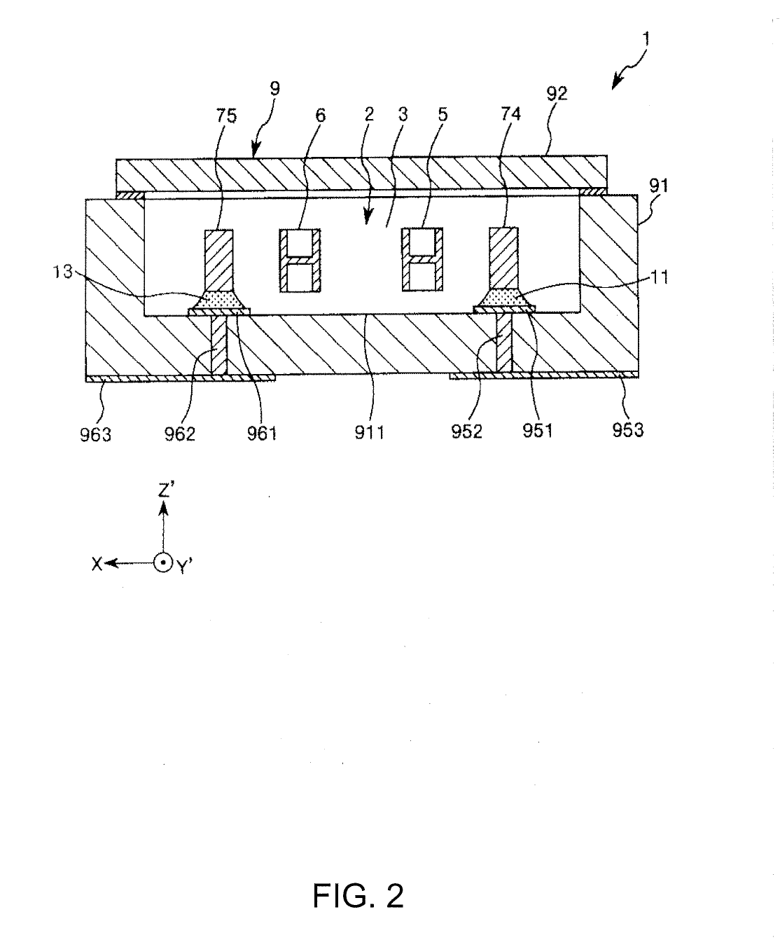

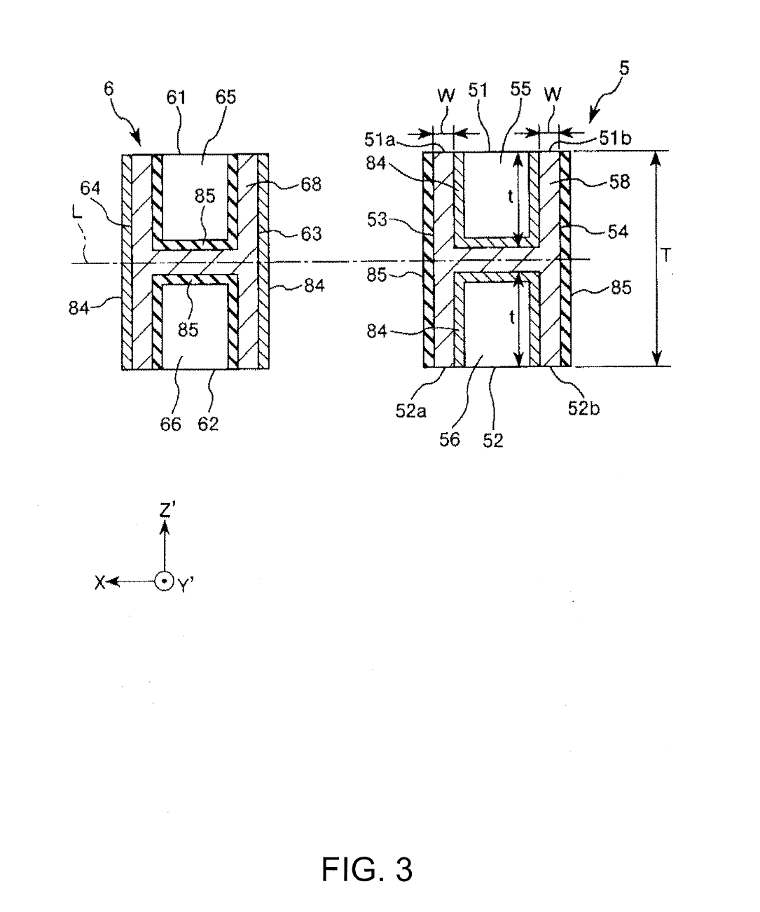

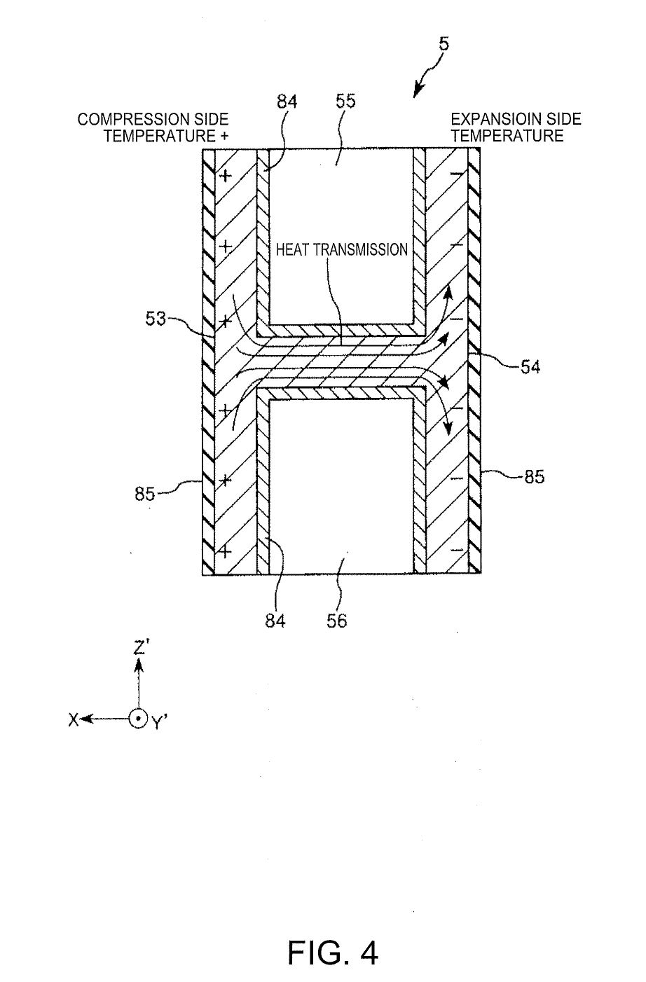

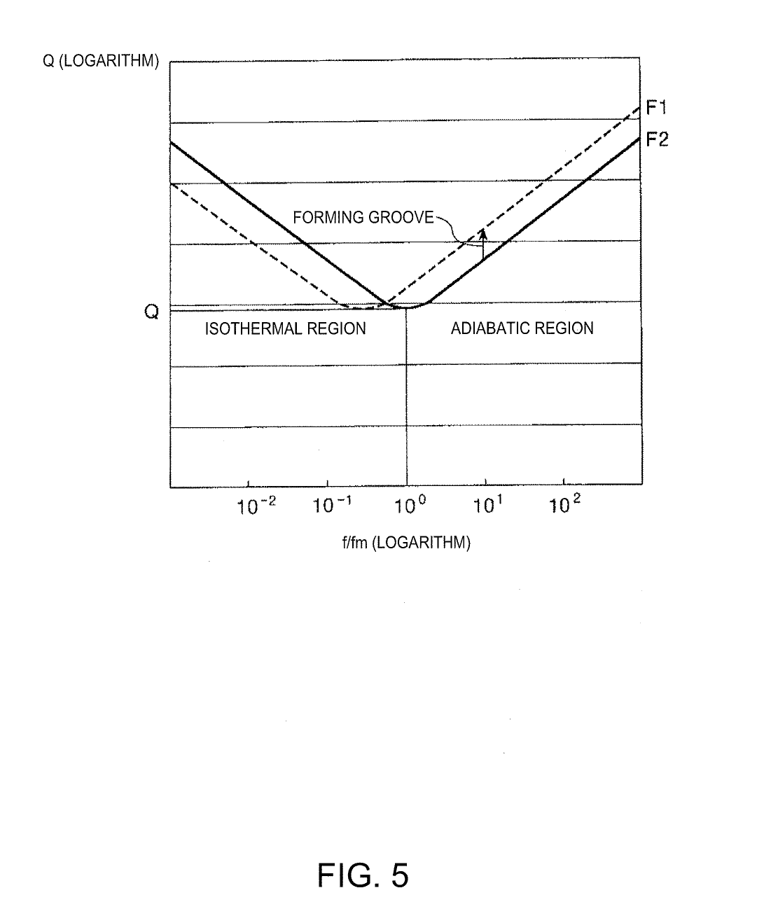

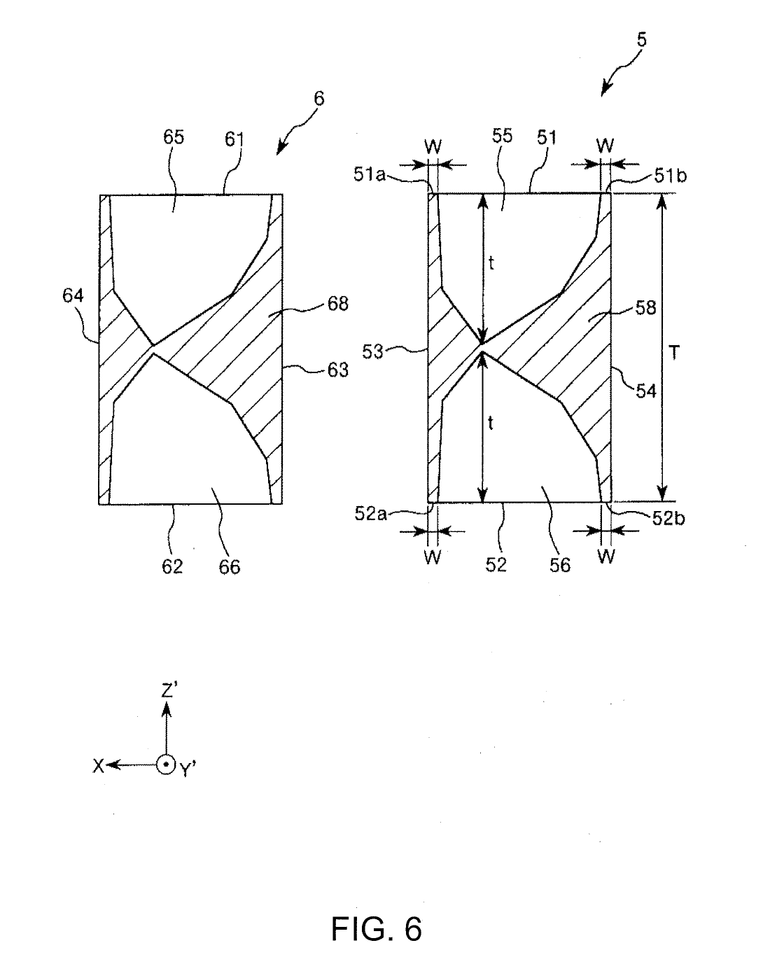

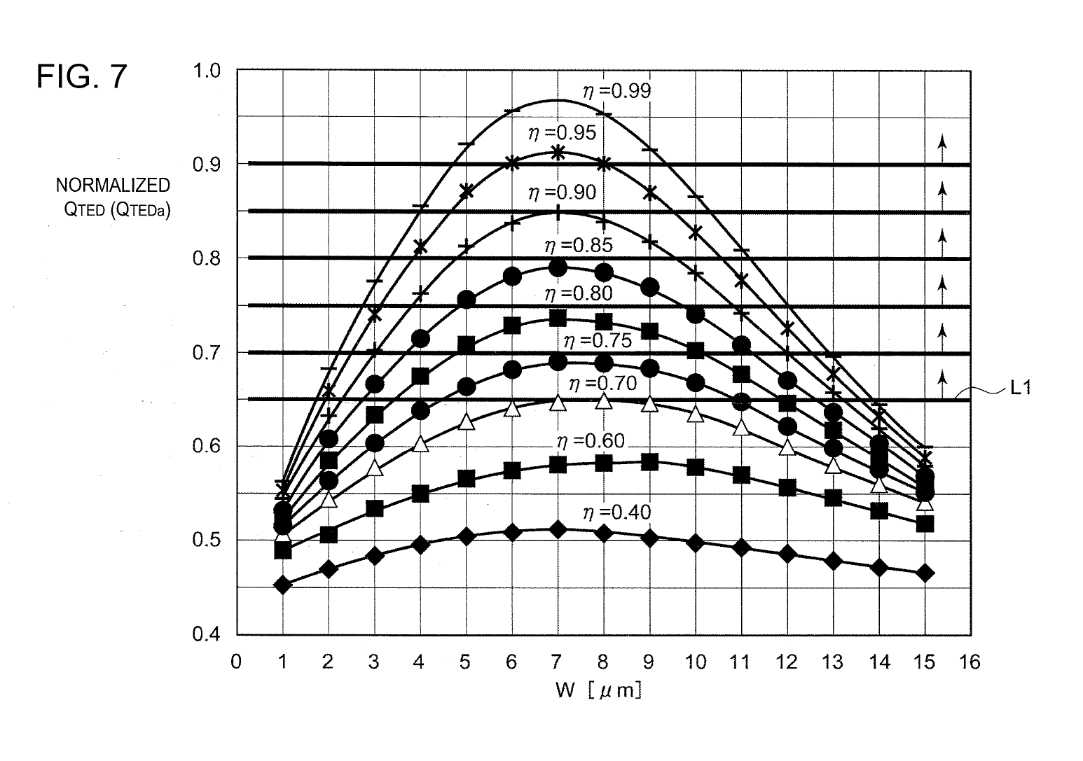

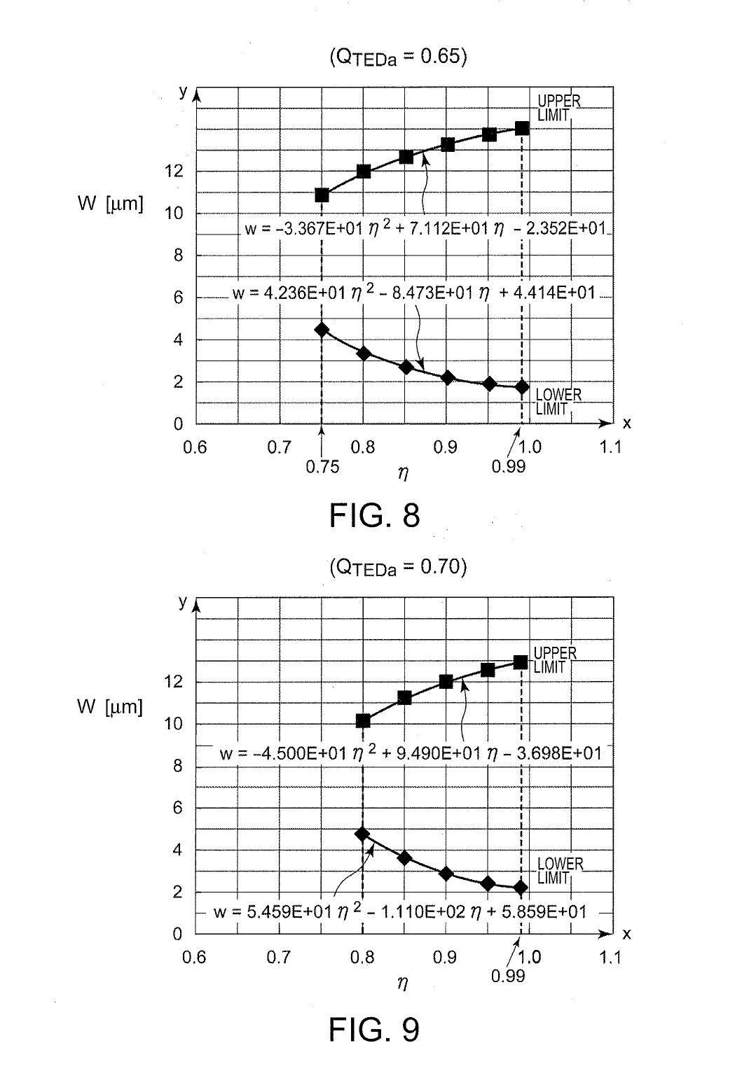

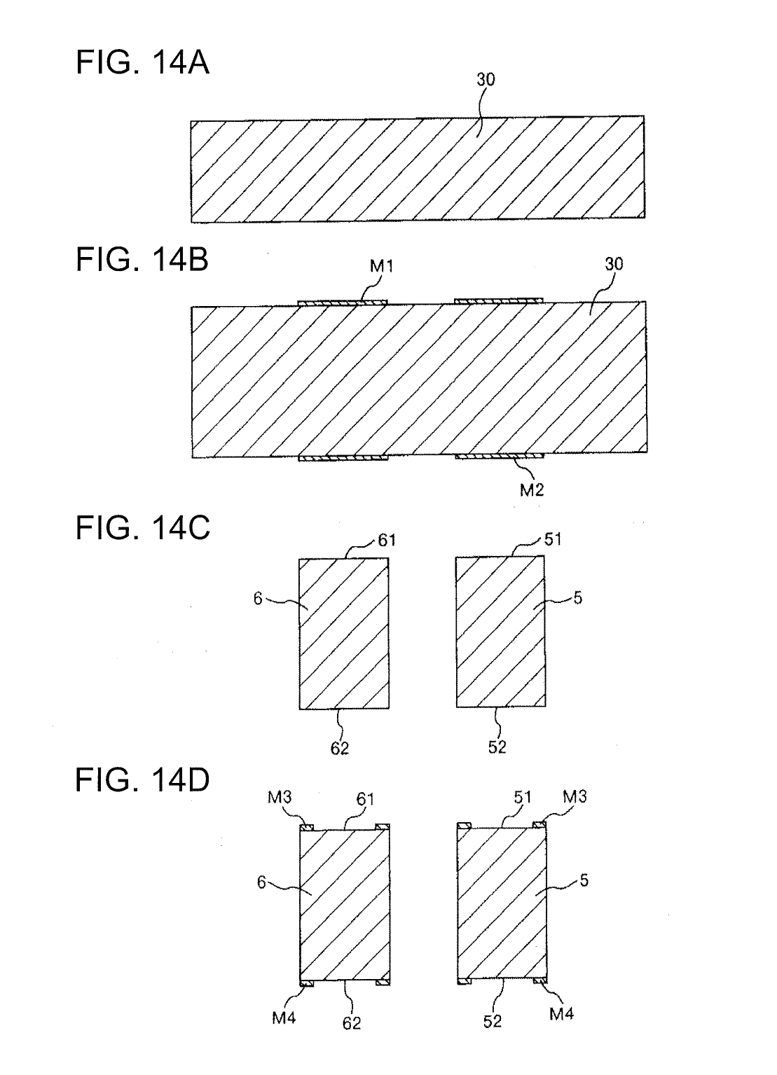

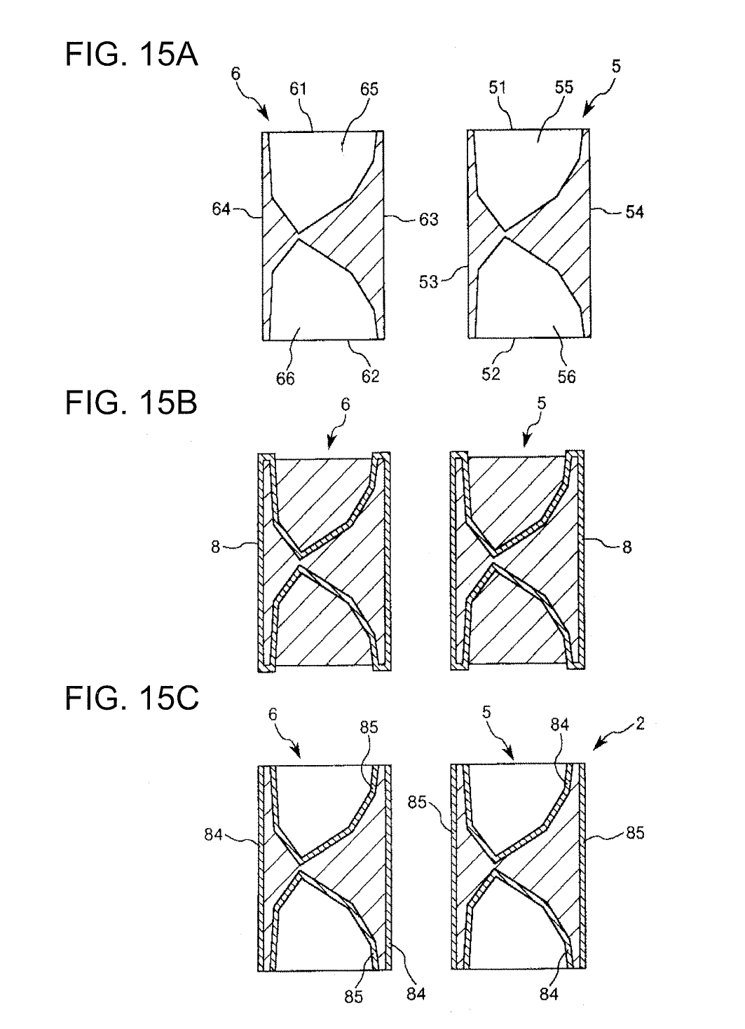

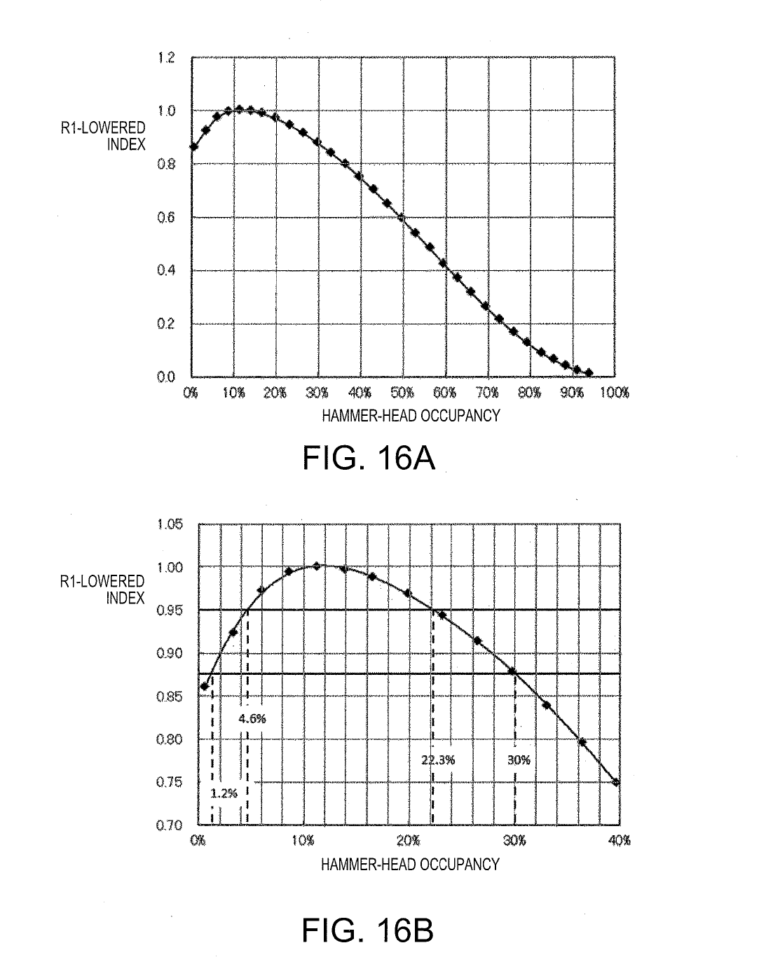

FIG. 1 is a plan view of a resonator according to the first embodiment of the invention, FIG. 2 is a cross-sectional view taken along line A-A in FIG. 1, FIG. 3 is a cross-sectional view (cross-sectional view taken along line B-B in FIG. 1) of a resonator element including the resonator illustrated in FIG. 1, FIG. 4 is a cross-sectional view of a vibration arm for illustrating thermal conduction during flexural vibration, FIG. 5 is a graph illustrating a relationship between a Q value and f/fm, FIG. 6 is a cross-sectional view illustrating the vibration arm formed through wet etching, FIG. 7 is a graph illustrating a relationship between W and Q_{TED}a, FIGS. 8 to 13 are graphs illustrating a relationship between η and W, FIGS. 14A to 15C are cross-sectional views for illustrating a manufacturing method of the resonator element illustrated in FIG. 1, and FIGS. 16A and 16B are graphs illustrating a relationship between a hammer head occupancy ratio and a R1-lowered index.

A resonator 1 illustrated in FIGS. 1 and 2 includes a resonator element 2 (resonator element according to the invention) and a package 9 in which the resonator element 2 is accommodated. Hereinafter, the resonator element 2 and the package 9 will be described in detail in this order.

### Resonator Element

As illustrated in FIGS. 1 to 3, the resonator element 2 according to the present embodiment includes a quartz crystal substrate (resonator blank) 3 and first and second driving electrodes 84 and 85 formed on the quartz crystal substrate 3. The first and second driving electrodes 84 and 85 are not illustrated in FIGS. 1 and 2, for the sake of convenience.

The quartz crystal substrate 3 is configured of a Z-cut quartz crystal sheet. A quartz crystal substrate in which a Z axis substantially matches a thickness direction is used as the Z-cut quartz crystal sheet. In the quartz crystal substrate 3, the thickness direction may match the Z axis but the Z axis is slightly inclined with respect to the thickness direction in terms of reducing a frequency-temperature change at about room temperature. That is, when the inclined angle is θ degrees (−5°≦θ≦15°) and a θ-degree-inclined axis of the Z axis is a Z′ axis such that the +Z side rotates toward a −Y direction of the Y axis and a θ-degree-inclined axis of the Y axis is a Y′ axis such that the +Y side rotates toward a +Z direction of the Z axis, about the X axis of an orthogonal coordinate system including an X axis as an electrical axis of the quartz crystal, a Y axis as a mechanical axis, and a Z axis as an optical axis, the quartz crystal substrate 3 has a thickness in a direction along the Z′ axis and has a main surface that is a surface having the X axis and the Y′ axis. The X axis, the Y′ axis, and the Z′ axis are illustrated in the drawings.

The quartz crystal substrate 3 has the Y′ axis direction in the longitudinal direction, the X axis direction in the width direction, and the Z′ axis direction in the thickness direction. In addition, the quartz crystal substrate 3 has substantially the same thickness across a substantially entire region (except for regions where grooves 55, 56, 57, and 58 which will be described later are formed). The thickness (length in the Z′ axis direction) T of the quartz crystal substrate 3 is not particularly limited, but preferably 110 μm to 150 μm, more preferably 120 μm to 130 μm. Accordingly, sufficient mechanical strength is obtained, in addition, a high Q value is obtained, a low crystal impedance (CI) value that is an equivalent series resistance is obtained, and it is possible to easily form a minute shape through wet etching. That is, when the thickness T of the quartz crystal substrate 3 is less than the above lower limit value, the Q value becomes low and the CI value becomes high depending on other conditions, and in addition, there is a concern that the quartz crystal substrate 3 is damaged due to an insufficient mechanical strength. In addition, when the thickness T of the quartz crystal substrate 3 exceeds the above upper limit value, it is difficult to form the minute shape by using a wet etching technique and in addition, there is a concern that an excessive increase in the size of the resonator element 2 is brought about.

Such a quartz crystal substrate 3 includes a proximal section 4, a pair of vibration arms 5 and 6 that extend from the proximal section 4, and a support section 7 that extends from the proximal section 4.

The proximal section 4 expands on an XY′ plane and has a sheet-like shape having a thickness in the Z′ axis direction. In addition, the support section 7 includes a branch section 71 that extends from the lower end of the proximal section 4 and branches in the X axis direction, connection arms 72 and 73 that extend from the branch section on both sides in the X axis direction, and support arms 74 and 75 that extend from the tip end portions of the connection arms 72 and 73 in the −Y′ axis direction.

The vibration arms 5 and 6 are provided side by side along the X axis direction (second direction) and extend from the end of the proximal section 4 on the −Y′ axis side in the −Y′ axis direction (first direction) to be parallel to each other. These vibration arms 5 and 6 each have a longitudinal shape of which the base end (end on the +Y′ axis side) becomes a fixed end and the tip end (end on the −Y axis side) becomes a free end. In addition, the vibration arms 5 and 6 include arm sections 58 and 68 that extend from the proximal section 4, respectively, and hammer-heads (broad-width sections) 59 and 69 that are provided on the tip end portions of the arm sections 58 and 68 and as a weight section having a broader width than the arm sections 58 and 68, respectively. Thus, the hammer-heads 59 and 69 are provided on the tip end portions of the vibration arms 5 and 6, and thereby it is possible to shorten the vibration arms 5 and 6 and to achieve miniaturization of the resonator element 2. In addition, since it is possible to lower a vibration speed of the vibration arms 5 and 6 when the vibration arms 5 and 6 are caused to vibrate at the same frequency than in the related art to an extent that the vibration arms 5 and 6 are shortened, it is possible to decrease air resistance produced when the vibration arms 5 and 6 vibrate, and the Q value becomes high at an equivalent degree, and it is possible to improve the vibration characteristics. Such vibration arms 5 and 6 have the same configuration (shape and size) as each other. Further, when the length of the vibration arms 5 and 6 is uniform, and a widened length (width) of the arm sections 58 and 68 along the second direction causes the resonance frequency of flexural vibration that is lowered by providing the hammer-heads 59 and 69 on the tip end portions of the vibration arms 5 and 6 to be maintained at the same resonance frequency as before the hammer-heads 59 and 69 are provided, a path for heat that is produced in the arm sections 58 and 68 during the flexural vibration to flow along the second direction of the arm sections 58 and 68 becomes long. As will be described later, a reduction of the thermoelastic loss in an adiabatic-like region causes a high Q value to be achieved and simultaneously it is possible to achieve a low CI value.

As illustrated in FIG. 3, the vibration arm 5 includes a pair of main surfaces 51 and 52 configured on the XY′ plane to be the front and the rear to each other and a pair of side surfaces 53 and 54 configured on a Y′Z′ plane that connects the pair of main surfaces 51 and 52 to each other. In addition, the vibration arm 5 includes a bottomed groove 55 that opens to the main surface 51 and a bottomed groove 56 that opens to the main surface 52. The grooves 55 and 56 extend in the Y′ axis direction, respectively. In addition, the grooves 55 and 56 extend to the tip end portion of the arm section 58, respectively, to include a base portion of the arm section 58 of the vibration arm 5. Such a vibration arm 5 has a substantial H-like cross-sectional shape at a portion where the grooves 55 and 56 are formed.

It is preferable that the grooves 55 and 56 are formed to be symmetrical with respect to a line L which bisects the length of the vibration arm 5 in the thickness direction. Accordingly, it is possible to decrease unnecessary vibration (specifically, oblique vibration having an out-of-plane component) of the vibration arm 5 and thus to cause the vibration arm 5 to vibrate efficiently in an in-plane direction of the quartz crystal substrate 3.

Similar to the vibration arm 5, the vibration arm 6 includes a pair of main surfaces 61 and 62 configured on the XY′ plane to be the front and the rear to each other and a pair of side surfaces 63 and 64 configured on a Y′Z′ plane that connects the pair of main surfaces 61 and 62 to each other. In addition, the vibration arm 6 includes a bottomed groove 65 that opens to the main surface 61 and a bottomed groove 66 that opens to the main surface 62. The grooves 65 and 66 extend in the Y′ axis direction, respectively. In addition, the grooves 65 and 66 extend to the tip end portion of the arm section 68, respectively, to include a base portion of the arm section 68 of the vibration arm 6. Such a vibration arm 6 has a substantial H-like cross-sectional shape at a portion where the grooves 65 and 66 are formed.

It is preferable that the grooves 65 and 66 are formed to be symmetrical with respect to the line L which bisects the length of the vibration arm 6 in the thickness direction. Accordingly, it is possible to decrease unnecessary vibration of the vibration arm 6 and thus to cause the vibration arm 6 to vibrate efficiently in the in-plane direction of the quartz crystal substrate 3.

In addition, as will be described later, when the grooves 55, 56, 65, and 66 are formed through wet etching, respectively, the bottom surfaces slope as illustrated in FIG. 6. Therefore, the grooves 55, 56, 65, and 66 do not have bottom surfaces with uniform depths (flat surfaces), respectively. Accordingly, the grooves 55, 56, 65, and 66 have high rigidity and high strength against impact or the like compared to a groove having a bottom surface with a uniform depth.

A pair of first driving electrodes 84 and a pair of second driving electrodes 85 are formed on the vibration arm 5. Specifically, one of the first driving electrodes 84 is formed on the inner surface of the groove 55 and the other is formed on the inner surface of the groove 56. In addition, one of the second driving electrodes 85 is formed on the side surface 53 and the other is formed on the side surface 54. Similarly, a pair of first driving electrodes 84 and a pair of second driving electrodes 85 are also formed on the vibration arm 6. Specifically, one of the first driving electrodes 84 is formed on the side surface 63 and the other is formed on the side surface 64. In addition, one of the second driving electrodes 85 is formed on the inner surface of the groove 65 and the other is formed on the inner surface of the groove 66. When an alternating voltage is applied between these first and second driving electrode 84 and 85, the vibration arms 5 and 6 vibrate at a predetermined frequency in the in-plane direction (XY′ plane direction) to repeat approaching and separating from each other.

A configuration of the first and second driving electrodes 84 and 85 is not particularly limited, and it is possible to form by using a metal material such as gold (Au), a gold alloy, platinum (Pt), aluminum (Al), an aluminum alloy, silver (Ag), a silver alloy, chromium (Cr), a chromium alloy, copper (Cu), molybdenum (Mo), niobium (Nb), tungsten (W), iron (Fe), titanium (Ti) cobalt (Co), zinc (Zn), zirconium (Zr), or the like, and a conductive material such as an indium tin oxide (ITO).

As above, the configuration of the resonator element 2 is described briefly. As described above, the grooves 55 and 56, and the grooves 65 and 66 are formed on the vibration arms 5 and 6 of the resonator element 2, respectively, and thereby it is possible to decrease the thermoelastic loss and thus to decrease the reduction of the Q value so as to exhibit good vibration characteristics. Hereinafter, this will be specifically described with the vibration arm 5 as an example.

The vibration arm 5 flexurally vibrates in the in-plane direction by applying an alternating voltage between the first and second driving electrodes 84 and 85. As illustrated in FIG. 4, during the flexural vibration, when the side surface 53 of the vibration arm 5 contracts the side surface 54 expands, but in contrast when the side surface 53 expands the side surface 54 contracts. Since, of the side surfaces 53 and 54, a temperature on the contracted surface side rises, and a temperature on the expanded surface side is lowered, a temperature difference occurs between the side surface 53 and the side surface 54, that is, in the vibration arm 5. A vibration energy loss occurs due to thermal conduction occurring from such a temperature difference. In this manner, the Q value of the resonator element 2 is reduced. Such a reduction of the Q value is also referred to as a thermoelastic effect and a loss of energy due to the thermoelastic effect is also referred to as a thermoelastic loss.

In a resonator element in a flexural vibration mode which has the configuration of the resonator element 2, when a flexural vibration frequency (mechanical flexural vibration frequency) f of the vibration arm 5 changes, the minimum Q value is obtained when the flexural vibration frequency of the vibration arm 5 matches a relaxation vibration frequency fm. The relaxation vibration frequency fm can be obtained from fm=1/(2πτ) (here, π in the expression is Pi and τ is relaxation time taken to temperature equilibration of the temperature difference due to the thermal conduction).

In addition, the relaxation vibration frequency fm can be obtained by the following expression (1).

fm=πk/(2ρCpa²) (1)

Here, π is the Pi, k is the thermal conductivity of the vibration arm 5 in the vibration direction, ρ is the mass density of the vibration arm 5, Cp is the thermal capacity of the vibration arm 5, and a is a width of the vibration arm 5 in the vibration direction. In a case where a constant of the material itself (that is, quartz crystal) of the vibration arm 5 is input for the thermal conductivity k, the mass density ρ, and the thermal capacity Cp, in expression (1), the obtained relaxation vibration frequency fm becomes a value in a case where the grooves 55 and 56 are not provided on the vibration arm 5.

As illustrated in FIG. 4, the grooves 55 and 56 are formed to be positioned between the side surfaces 53 and 54 in the vibration arm 5. Therefore, a heat transfer path for the temperature equilibration of the temperature difference of the side surfaces 53 and 54 which occurs during the flexural vibration of the vibration arm 5 is formed to bypass the grooves 55 and 56 and the heat transfer path becomes longer than the linear distance (shortest distance) between the side surfaces 53 and 54. Therefore, the relaxation time T becomes long compared to a case where the grooves 55 and 56 are not provided on the vibration arm 5 and the relaxation vibration frequency fm becomes low.

FIG. 5 is a graph illustrating dependence of the Q value of the resonator element in the flexural vibration mode on f/fm. In FIG. 5, a curved line F1 illustrated as a dotted line shows a case in which the grooves are formed on the vibration arm as in the resonator element 2 (case in which the vibration arm has an H-like cross-sectional shape), a curved line F2 illustrated as a solid line shows a case in which the grooves are not formed on the vibration arm (case in which the vibration arm has a rectangular cross-sectional shape).

As illustrated in FIG. 5, shapes of the curved lines F1 and F2 do not change, but the curved line F1 is shifted toward a frequency lowering direction with respect to the curved line F2 in accordance with the lowering of the relaxation vibration frequency fm. Thus, when a relationship of f/fm>1 is satisfied, normally, the Q value of the resonator element in which the grooves are formed on the vibration arm is higher than the Q value of the resonator element in which the grooves are not formed on the vibration arm.

In FIG. 5, a region where f/fm<1 is referred to as an isothermal-like region and, in the isothermal-like region, as f/fm becomes smaller, the Q value becomes higher. This is because, as the mechanical frequency of the vibration arm becomes low (vibration of the vibration arm delays), it is difficult for the temperature difference as described above in the vibration arm to occur. Meanwhile, a region where f/fm>1 is referred to as an adiabatic-like region and, in the adiabatic-like region, as f/fm becomes greater, the Q value becomes higher. This is because, as the mechanical frequency of the vibration arm becomes high, a temperature changes up and down at such a high speed in the side surfaces that there is no time for the thermal conduction as described above to occur. Therefore, when a relationship of f/fm>1 is satisfied, it can also mean that f/fm exists in the adiabatic-like region.

Since a constituent material (metal material) of the first and second driving electrodes 84 and 85 is high in thermal conductivity compared to crystal which is a constituent material of the vibration arms 5 and 6, the thermal conduction is actively performed in the vibration arm 5 through the first driving electrode 84 and the thermal conduction is actively performed in the vibration arm 6 through the second driving electrode 85. When the thermal conduction is actively performed through the first and second driving electrodes 84 and 85 as described above, the relaxation time τ is likely to be shortened. It is preferable that the occurrence of thermal conduction as described above is suppressed or reduced by dividing the first driving electrode 84 into the side surface 53 side and the side surface 54 side in the bottom surfaces of the grooves 55 and 56 in the vibration arm 5, and dividing the second driving electrode 85 into the side surface 63 side and the side surface 64 side in the bottom surfaces of the grooves 65 and 66 in the vibration arm 6. As a result, the relaxation time τ is prevented to be short, and the resonator element 2 having a higher Q value is obtained.

As above, the thermoelastic loss is described.

In the resonator element 2, when fm=πk/(2ρCpa²), a range of f/fm>1 is satisfied, in addition, the grooves 55, 56, 65, and 66 are formed to have predetermined shapes in the vibration arms 5 and 6, and thereby the resonator element 2 is configured to obtain a higher Q value than in a resonator element of the related art. Hereinafter, configurations of the grooves 55, 56, 65, and 66 formed on the vibration arms 5 and 6 will be specifically described. Since the vibration arms 5 and 6 have the same configuration as each other, description of the grooves 55 and 56 formed on the vibration arm 5 is provided representatively and description of the grooves 65 and 66 formed on the vibration arm 6 is omitted.

As illustrated in FIG. 3, in the resonator element 2, widths (length in the X axis direction) of banks (main surfaces provided side by side interposing the groove 55 therebetween along the width direction orthogonal to the longitudinal direction of the vibration arm 5) 51a and 51b which are positioned on both sides of the groove 55 of the main surface 51 in the X axis direction are substantially the same as each other. When widths of the banks 51a and 51b are W, a thickness (length in the Z′ axis direction) of the vibration arm 5 is T, a sum of the maximum depths of the grooves 55 and 56 is to (2t in an example illustrated in FIG. 3), and ta/T is η, a relationship shown by the following expression (2) is satisfied.

4.236×10×η²−8.473×10×η+4.414×10 [μm]≦W [μm]≦−3.367×10×η²+7.112×10×η−2.352×10 [μm] (2)

wherein 0.75≦η<1.00

Here, W is a width of the main surface 51 between an outer edge of the vibration arm 5 and the groove 55 in a plan view along a direction (X axis direction) orthogonal to the extending direction (−Y′ axis direction) of the vibration arm 5.

Widths of the banks (portions) 52a and 52b of the main surface 52 positioned on both sides of the groove 56 in the X axis direction satisfy the same relationship.

A region S in which the expression (2) is satisfied exists on at least a part of the vibration arm 5, and thereby it is possible to obtain the resonator element 2 in which better vibration characteristics are exhibited than in the related art. A region S in which the expression (2) is satisfied may exist on a part of the vibration arm 5 in the longitudinal direction, but it is preferable that the region S exists to include the base portion of the vibration arm 5. The base portion is a portion in which flexural deformation occurs greatly in the vibration arm 5 and a portion which is likely to have influence on the entire vibration characteristics of the vibration arm 5. Therefore, the region S is caused to exist at least on the base portion, and thereby it is possible to obtain the resonator element 2 in which better vibration characteristics are more reliably and effectively exhibited than in the related art. In addition, in other words, the region S is caused to exist at least on a portion of the vibration arm 5 where an amount of the flexural deformation is greatest, and thereby it is possible to obtain the resonator element 2 in which better vibration characteristics are more reliably and effectively exhibited than in a product of the related art. To be more specific, it is preferable that the region S exists to contain a region formed of 30% of the length of the arm section 58 toward the tip end portion from the base portion of the arm section 58.

As illustrated in FIG. 1, in the resonator element 2 according to the embodiment, the arm section 58 is configured to have substantially the same width and depth across a substantially entire region (region S1) except for both end portions, and in addition, the grooves 55 and 56 are formed to have substantially the same width and depth across an entire region (region S2). In the resonator element 2, since a region in which such regions S1 and S2 are overlapped with each other configures the region S, it is possible to cause a lengthy region S to exist in the longitudinal direction of the vibration arm 5. Thus, the effect described above becomes remarkable.

The above expression (2) is a condition that the Q value obtained taking only the thermoelastic loss into account is Q_{TED} and Q_{TED} is higher than a predetermined value.

Hereinafter, the following description is performed in which Q_{TED} is normalized. The normalization of the Q_{TED} is performed with Q_{TED} which is estimated when η infinitely approaches 1 as 1. That is, when Q_{TED} which is estimated when η infinitely approaches 1 is Q_{TED} (η=1) Q_{TED} before the normalization is Q_{TED}b, and the normalized Q_{TED} is Q_{TED}a, Q_{TED}a is represented by Q_{TED}b/Q_{TED} (η=1).

First, the above expression (2) is a condition of Q_{TED}a≧0.65. Conditions of Q_{TED}a≧0.70, Q_{TED}a≧0.75, Q_{TED}a≧0.80, Q_{TED}a≧0.85, and Q_{TED}a≧0.90 are as follows, respectively.

Q_{TED}a≧0.70

A condition of Q_{TED}a≧0.70 satisfies a relationship represented by the following expression (3).

5.459×10×η²−1.110×10²×η+5.859×10 [μm]≦W [μm]−4.500×10×η²+9.490×10×η−3.698×10 [μm] (3)

wherein 0.80≦η<1.00
Q_{TED}a≧0.75

A condition of Q_{TED}a≧0.75 satisfies a relationship represented by the following expression (4).

6.675×10×η²−1.380×10²×η+7.392×10 [μm]≦W [μm]≦−5.805×10×η²+1.228×10²×η−5.267×10 [μm] (4)

wherein 0.85≦η<1.00
Q_{TED}a≧0.80

A condition of Q_{TED}a≧0.80 satisfies a relationship represented by the following expression (5).

7.752×10×η²−1.634×10²×η+8.903×10 [μm]≦W [μm]≦−6.993×10×η²+1.496×10²×η−6.844×10 [μm] (5)

wherein 0.90≦η<1.00
Q_{TED}a≦0.85

A condition of Q_{TED}a≧0.85 satisfies a relationship represented by the following expression (6).

−1.847×10×η+2.217×10 [μm]≦W [μm]≦1.189×10×η−8.433 [μm] (6)

wherein 0.95≦η<1.00
Q_{TED}a≧0.90

A condition of Q_{TED}a≧0.90 satisfies a relationship represented by the following expression (6′).

−3.300×10×η+3.730×10 [μm]≦W [μm]≦3.302×10×η−2.333×10 [μm] (6′)

wherein 0.95≦η<1.00

Hereinafter, these conditions are demonstrated on the basis of an analysis result by simulations conducted by the inventor. A simulation is used representatively to which the resonator element 2 with flexural vibration frequency (mechanical flexural vibration frequency) f=32.768 kHz which is formed through patterning the Z-cut quartz crystal sheet is applied. The inventor confirms that, in a range where the flexural vibration frequency f is 32.768 kHz±1 kHz, there is substantially no difference from the analysis result of the simulation which will be shown later.

In addition, in the present simulation, the resonator element 2 in which the quartz crystal substrate 3 is patterned through wet etching is used. Thus, the grooves 55 and 56 have shapes in which a crystal surface of the quartz crystal appears as illustrated in FIG. 6. FIG. 6 illustrates a cross section corresponding to a cross section taken along line B-B in FIG. 1. Since an etching rate in the −X axis direction is lower than the etching rate in the +X axis direction, the side surface in the −X axis direction has a relatively gentle slope and the side surface in the +X axis direction has a nearly perpendicular slope.

In addition, the size of the quartz crystal substrate 3 of the resonator element 2 used in the present simulation is 1160 μm in length, 520 μm in width, and 120 μm in thickness, that is, each thickness T of the vibration arms 5 and 6. The inventor confirms that, even when the length, width or thickness is changed, there is substantially no difference from the analysis result of the simulation which will be shown later. In addition, in the present simulation, the resonator element 2 is used, in which the first and second driving electrodes 84 and 85 are not formed.

FIG. 7 is a graph illustrating a relationship between the widths W of the banks 51a, 51b, 52a, and 52b and Q_{TED}a when η is respectively 0.40, 0.60, 0.70, 0.75, 0.80, 0.85, 0.90, 0.95, and 0.99. In addition, the lower limit value Qₘᵢₙ of Q_{TED}a to be obtained in the resonator element 2 is 0.65 and is illustrated by the line L1. Q_{TED}a becomes the value or higher and thereby it is possible to exhibit good vibration characteristics.

FIG. 7 shows that, when is 0.75, 0.80, 0.85, 0.90, 0.95, and 0.99, a region where Q_{TED}a is 0.65 or higher exists. Accordingly, as described above, when Q_{TED}a≧0.65, it is shown that there is a need to satisfy a relationship of “0.75≦η<1.00”.

In addition, FIG. 8 is a graph obtained by plotting each point at which each graph in FIG. 7 and Q_{TED}a=0.65 cross and, in a case where Q_{TED}a=0.65 (Qₘᵢₙ), illustrating a relationship between η and W.

In this case, a graph representing the lower limit value of W is represented by the following expression (7).

W [μm]=4.236×10×η²−8.473×10×η+4.414×10 (7)

In addition, a graph representing the upper limit value of W is represented by the following expression (8).

W [μm]=−3.367×10×η²+7.112×10×η−2.352×10 [μm] (8)

Thus, FIG. 8 shows that a relationship represented by the above expression (2) is satisfied and thereby the resonator element 2 having Q_{TED}a of 0.65 or higher is obtained. As above, the above expression (2) is satisfied, and thereby it is demonstrated that the resonator element 2 is achieved, in which the high Q_{TED}a of 0.65 or higher and good vibration characteristics are obtained.

Similarly, FIG. 7 shows that, when η is 0.80, 0.85, 0.90, 0.95, and 0.99, a region where Q_{TED}a is 0.70 or higher exists. Accordingly, as described above, when Q_{TED}a≧0.70, it is shown that there is a need to satisfy a relationship of “0.80≦η<1.00”.

In addition, FIG. 9 is a graph obtained by plotting each point at which each graph in FIG. 7 and Q_{TED}a=0.70 cross and, in a case where Q_{TED}a=0.70 (Qₘᵢₙ), illustrating a relationship between η and W.

In this case, a graph representing the lower limit value of W is represented by the following expression (9).

W [μm]=5.459×10×η²−1.110×10²×η+5.859×10 [μm] (9)

In addition, a graph representing the upper limit value of W is represented by the following expression (10).

W [μm]=−4.500×10×η²+9.490×10×η−3.698×10 [μm] (10)

Thus, FIG. 9 shows that a relationship represented by the above expression (3) is satisfied and thereby the resonator element 2 having Q_{TED}a of 0.70 or higher is obtained. As above, the above expression (3) is satisfied, and thereby it is demonstrated that the resonator element 2 is achieved, in which the high Q_{TED}a of 0.70 or higher and good vibration characteristics are obtained.

Similarly, FIG. 7 shows that, when η is 0.85, 0.90, 0.95, and 0.99, a region where Q_{TED}a is 0.75 or higher exists. Accordingly, as described above, when Q_{TED}a≧0.75, it is shown that there is a need to satisfy a relationship of “0.85≦η<1.00”.

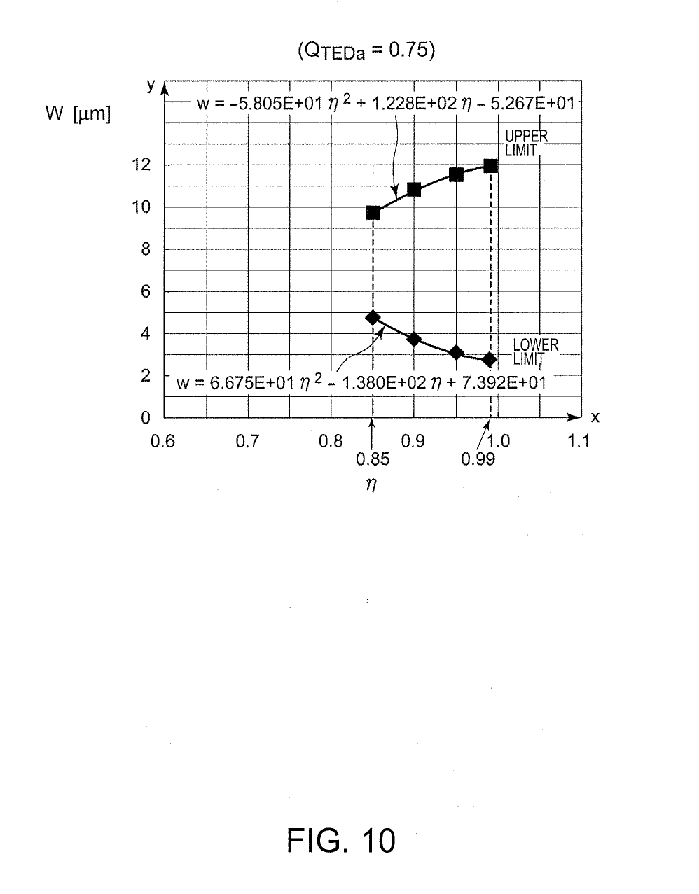

In addition, FIG. 10 is a graph obtained by plotting each point at which each graph in FIG. 7 and Q_{TED}a=0.75 cross and, in a case where Q_{TED}a=0.75 (Qₘᵢₙ) illustrating a relationship between η and W.

In this case, a graph representing the lower limit value of W is represented by the following expression (11).

W [μm]=6.675×10×η²−1.380×10²×η+7.392×10 [μm] (11)

In addition, a graph representing the upper limit value of W is represented by the following expression (12).

W [μm]=−5.805×10×η²+1.228×10²×η−5.267×10 [μm] (12)

Thus, FIG. 10 shows that a relationship represented by the above expression (4) is satisfied and thereby the resonator element 2 having Q_{TED}a of 0.75 or higher is obtained. As above, the above expression (4) is satisfied, and thereby it is demonstrated that the resonator element 2 is achieved, in which the high Q_{TED}a of 0.75 or higher and good vibration characteristics are obtained.

Similarly, FIG. 7 shows that, when η is 0.90, 0.95, and 0.99, a region where Q_{TED}a is 0.80 or higher exists. Accordingly, as described above, when Q_{TED}a it is shown that there is a need to satisfy a relationship of “0.907≦η<1.00”.

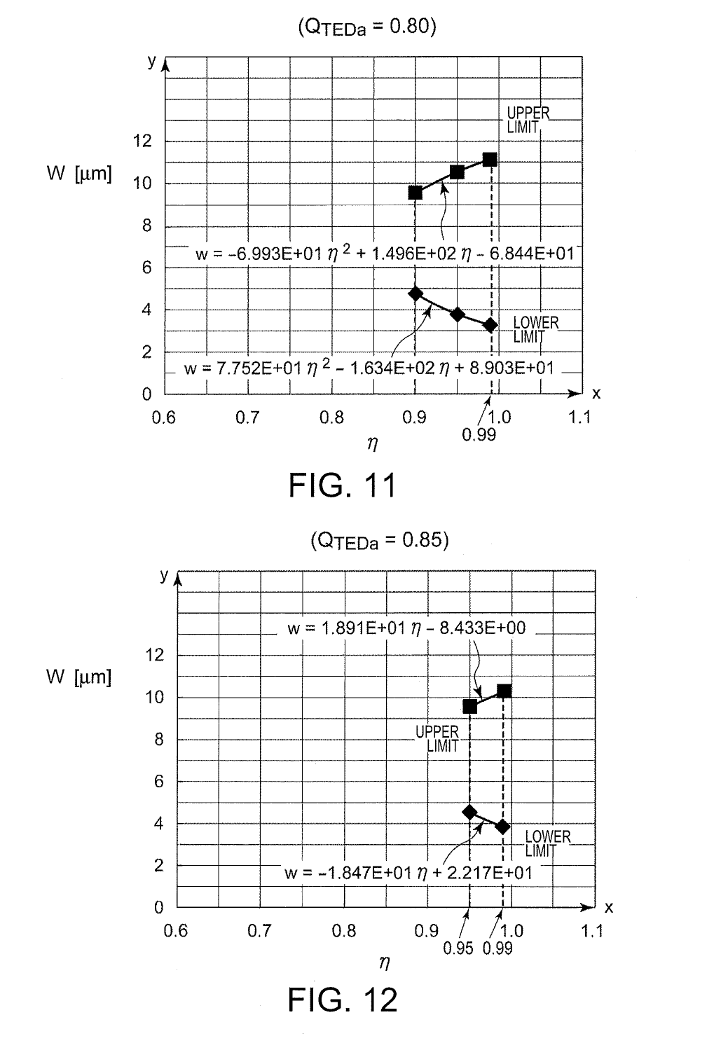

In addition, FIG. 11 is a graph obtained by plotting each point at which each graph in FIG. 7 and Q_{TED}a=0.80 cross and, in a case where Q_{TED}a=0.80 (Qₘᵢₙ), illustrating a relationship between η and W.

In this case, a graph representing the lower limit value of W is represented by the following expression (13).

W [μm]=7.752×10×η²−1.634×10²×η+8.903×10 [μm] (13)

In addition, a graph representing the upper limit value of W is represented by the following expression (14).

W [μm]=−6.993×10×η²+1.496×10²×η−6.844×10 [μm] (14)

Thus, FIG. 11 shows that a relationship represented by the above expression (5) is satisfied and thereby the resonator element 2 having Q_{TED}a of 0.80 or higher is obtained. As above, the above expression (5) is satisfied, and thereby it is demonstrated that the resonator element 2 is achieved, in which the high Q_{TED}a of 0.80 or higher and good vibration characteristics are obtained.

Similarly, FIG. 7 shows that, when η is 0.95, and 0.99, a region where Q_{TED}a is 0.85 or higher exists. Accordingly, as described above, when Q_{TED}a≧0.85, it is shown that there is a need to satisfy a relationship of “0.95≦η<1.00”.

In addition, FIG. 12 is a graph obtained by plotting each point at which each graph in FIG. 7 and Q_{TED}a=0.85 cross and, in a case where Q_{TED}a=0.85 (Qₘᵢₙ), illustrating a relationship between η and W.

In this case, a graph representing the lower limit value of W is represented by the following expression (15).

W [μm]=−1.847×10×η+2.217×10 [μm] (15)

In addition, a graph representing the upper limit value of W is represented by the following expression (16).

W [μm]=1.189×10×η−8.433 [μm] (16)

Thus, FIG. 12 shows that a relationship represented by the above expression (6) is satisfied and thereby the resonator element 2 having Q_{TED}a of 0.85 or higher is obtained. As above, the above expression (6) is satisfied, and thereby it is demonstrated that the resonator element 2 is achieved, in which the high Q_{TED}a of 0.85 or higher and good vibration characteristics are obtained.

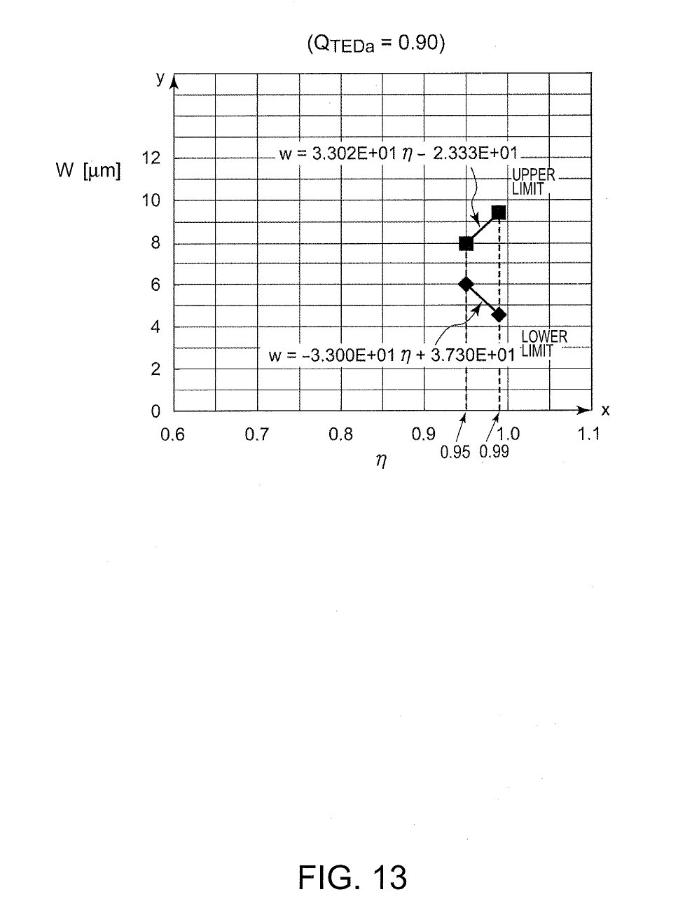

In addition, FIG. 13 is a graph obtained by plotting each point at which each graph in FIG. 7 and Q_{TED}a=0.90 cross and, in a case where Q_{TED}a=0.90 (Qₘᵢₙ), illustrating a relationship between η and W.

In this case, a graph representing the lower limit value of W is represented by the following expression (15′).

W=−3.300×10×η+3.730×10 [μm] (15′)

In addition, a graph representing the upper limit value of W is represented by the following expression (16′).

W=3.302×10×η−2.333×10 [μm] (16′)

Thus, FIG. 13 shows that a relationship represented by the above expression (6′) is satisfied and thereby the resonator element 2 having Q_{TED}a of 0.90 or higher is obtained. As above, the above expression (6′) is satisfied, and thereby it is demonstrated that the resonator element 2 is achieved, in which the high Q_{TED}a of 0.90 or higher and good vibration characteristics are obtained.

Next, a relationship between the entire lengths of the vibration arms 5 and 6 and the lengths of the hammer-heads 59 and 69 will be described. Since the vibration arms 5 and 6 have the same configuration as each other, the vibration arm 5 is described representatively, and the description of the vibration arm 6 is omitted.

As illustrated in FIG. 1, when the length (length in the Y′ axis direction) of the vibration arm 5 in the longitudinal direction (extending direction) is L and the length (length in the Y′ axis direction) of the hammer-head 59 in the longitudinal direction is H, the vibration arm 5 satisfies a relationship of 0.012<H/L<0.30. As long as the relationship is satisfied, the relationship is not particularly limited, but it is preferable that a relationship of 0.046<H/L<0.223 be satisfied. Since such a relationship is satisfied, and thereby the CI value of the resonator element 2 is suppressed to be low, the resonator element 2 is achieved, in which the vibration loss is small and good vibration characteristics are obtained.

The hammer-head 59 is formed as a region of which the width is at least 1.5 times the width (length in the X axis direction) of the arm section 58. In addition, a tapered section positioned on the outer side of the base portion of the arm section 58 is ended at the base end of the vibration arm 5.

The relationship of 1.2%<H/L<30.0% and a relationship of 1.5≦W2/W1≦10.0 are satisfied, and thereby it is demonstrated that the above effects are exhibited, on the basis of the simulation result. The present simulation was performed by using a single vibration arm 5. In addition, the vibration arm 5 used in the present simulation is configured of a quartz crystal Z sheet (rotation angle of 0°) In addition, the size of the vibration arm 5 is 1210 μm in the entire length L, 100 μm in thickness, 98 μm in the width of the arm section 58, 172 μm in the thickness of the hammer-head 59, 45 μm in depth t of both of the grooves 55 and 56, and 6.5 μm in the width W of each of the banks 51a and 51b. In such a vibration arm 5, the length H of the hammer-head 59 was changed and the simulation was conducted. The inventor confirms that, even when the size of the vibration arm 5 is changed, the same tendency is achieved as the simulation result which will be described later.

Table 1 below represents a change of the CI value when the size H of the hammer-head 59 is changed. In the present simulation, the CI value of each sample is calculated as follows. First, a Q value is obtained taking only the thermoelastic loss into account by using a finite element method. Next, since the Q value has frequency dependence, the obtained Q value is converted into a Q value at the time of 32.768 kHz (F-converted Q value). Next, R1 (CI value) is calculated based on the Q value after the F conversion. Next, since the CI value has frequency dependence, the obtained R1 is converted into R1 at the time of 32.768 kHz and an inverse number thereof is taken as “R1-lowered index”. The R1-lowered index is an index when the maximum inverse number in all of the simulations becomes 1. This means that the closer the R1-lowered index is to 1, the smaller the CI value becomes. FIG. 16A illustrates a graph obtained by plotting hammer-head occupancy (H/L) in the abscissa and the R1-lowered index on the ordinate, and FIG. 16B is an enlarged graph of a part of FIG. 16A.

A method of conversion of the Q value into a Q value after the F conversion is as follows.

Using the following expressions (31) and (32), calculation is performed as follows.

f₀=πk/(2ρCpa²) (31)

Q={ρCp/(Cα²H)}×[{1+(f/f₀)²}/(f/f₀)] (32)

Here, π in the expressions (31) and (32) is the Pi, k is the thermal conductivity of the vibration arm 5 in the width direction, ρ is the mass density, Cp is the thermal capacity, C is an elastic stiffness constant of expansion of the vibration arm 5 in the longitudinal direction, α is a coefficient of thermal expansion of the vibration arm 5 in the longitudinal direction, H is an absolute temperature, and f is an eigenfrequency. In addition, a is a width (effective width) obtained when the vibration arm 5 is considered to have a flat sheet-like shape. Even when the grooves 55 and 56 are not formed on the vibration arm 5, it is possible to perform the conversion into the F-converted Q value by using the value of a.

First, the eigenfrequency of the vibration arm 5 used in the simulation is F1, the obtained Q value is Q1, f=F1 and Q=Q1 using the expressions (31) and (32), and then the value of a is obtained. Next, a value of Q is calculated by the expression (32) using the obtained a and in addition, f=32.768 kHz. The obtained Q value becomes the F-converted Q value.

TABLE 1

| | | Eigenfrequency | | F-converted | | | R1-lowered |
|---|---|---|---|---|---|---|---|
| | H/L | f1 [Hz] | Q1 | Q value | R1 [Ω] | 1/R1 | index |
| SIM001 | 0.6% | 7.38E+04 | 159.398 | 76.483 | 3.50E+03 | 1.270E−04 | 0.861 |
| SIM002 | 3.3% | 5.79E+04 | 135.317 | 76.606 | 4.15E+03 | 1.363E−04 | 0.923 |
| SIM003 | 6.0% | 4.99E+04 | 120.906 | 79.442 | 4.58E+03 | 1.435E−04 | 0.972 |
| SIM004 | 8.6% | 4.48E+04 | 111.046 | 81.157 | 4.98E+03 | 1.467E−04 | 0.994 |
| SIM005 | 11.2% | 4.13E+04 | 103.743 | 82.223 | 5.37E+03 | 1.476E−04 | 1.000 |
| SIM006 | 13.9% | 3.88E+04 | 98.038 | 82.843 | 5.74E+03 | 1.471E−04 | 0.997 |
| SIM007 | 16.5% | 3.68E+04 | 93.507 | 83.225 | 6.10E+03 | 1.458E−04 | 0.988 |
| SIM008 | 19.8% | 3.49E+04 | 88.856 | 83.328 | 6.56E+03 | 1.430E−04 | 0.969 |
| SIM009 | 23.1% | 3.35E+04 | 85.017 | 83.115 | 7.02E+03 | 1.393E−04 | 0.944 |
| SIM010 | 26.4% | 3.24E+04 | 81.772 | 82.657 | 7.50E+03 | 1.348E−04 | 0.914 |
| SIM011 | 29.8% | 3.16E+04 | 78.811 | 81.824 | 8.01E+03 | 1.296E−04 | 0.878 |
| SIM012 | 33.1% | 3.09E+04 | 76.247 | 80.864 | 8.56E+03 | 1.239E−04 | 0.839 |
| SIM013 | 36.4% | 3.04E+04 | 73.813 | 79.591 | 9.17E+03 | 1.176E−04 | 0.796 |
| SIM014 | 39.7% | 3.00E+04 | 71.409 | 77.963 | 9.87E+03 | 1.106E−04 | 0.749 |
| SIM015 | 43.0% | 2.98E+04 | 69.077 | 76.078 | 1.07E+04 | 1.032E−04 | 0.699 |
| SIM016 | 46.3% | 2.96E+04 | 66.818 | 73.978 | 1.16E+04 | 9.557E−05 | 0.648 |
| SIM017 | 49.6% | 2.95E+04 | 64.449 | 71.494 | 1.27E+04 | 8.750E−05 | 0.593 |
| SIM018 | 52.9% | 2.96E+04 | 62.042 | 68.733 | 1.40E+04 | 7.928E−05 | 0.537 |
| SIM019 | 56.2% | 2.97E+04 | 59.670 | 65.800 | 1.55E+04 | 7.104E−05 | 0.481 |
| SIM020 | 59.5% | 3.00E+04 | 57.018 | 62.370 | 1.75E+04 | 6.257E−05 | 0.424 |
| SIM021 | 62.8% | 3.03E+04 | 54.502 | 58.918 | 1.98E+04 | 5.447E−05 | 0.369 |
| SIM022 | 86.1% | 3.08E+04 | 51.676 | 54.983 | 2.29E+04 | 4.640E−05 | 0.314 |
| SIM023 | 69.4% | 3.14E+04 | 48.788 | 50.857 | 2.69E+04 | 3.871E−05 | 0.262 |
| SIM024 | 72.7% | 3.23E+04 | 45.699 | 46.416 | 3.23E+04 | 3.140E−05 | 0.213 |
| SIM025 | 76.0% | 3.33E+04 | 42.398 | 41.687 | 4.00E+04 | 2.461E−05 | 0.167 |
| SIM026 | 79.3% | 3.47E+04 | 39.084 | 36.902 | 5.08E+04 | 1.857E−05 | 0.126 |
| SIM027 | 82.6% | 3.65E+04 | 35.523 | 31.872 | 6.77E+04 | 1.325E−05 | 0.090 |
| SIM028 | 85.5% | 3.86E+04 | 32.226 | 27.387 | 9.12E+04 | 9.314E−06 | 0.063 |
| SIM029 | 88.3% | 4.13E+04 | 28.763 | 22.842 | 1.13E+05 | 6.056E−06 | 0.041 |
| SIM030 | 91.1% | 4.50E+04 | 24.913 | 18.132 | 2.11E+05 | 3.448E−06 | 0.023 |
| SIM031 | 93.9% | 5.07E+04 | 24.042 | 13.614 | 4.04E+05 | 1.602E−06 | 0.011 |

The inventor has obtained the resonator element 2 in which the R1-lowered index is 0.87 or greater. As understood in Table 1 and FIGS. 16A and 16B, in the simulations (SIM002 to SIM011) in which a relationship of 1.2%<H/L<30.0% is satisfied, the R1-lowered index becomes a goal of 0.87 or greater. In particular, in the simulations (SIM003 to SIM008) in which a relationship of 4.6%<H/L<22.3% is satisfied, the R1-lowered index exceeds 0.95, and thus it is known that the CI value becomes lower. From the simulation results as above, the relationship of 1.2%<H/L<30.0% is satisfied, and thereby it is demonstrated that the resonator element 2 in which the CI value is sufficiently suppressed is obtained.

### Package

As illustrated in FIGS. 1 and 2, the package 9 includes a box-like base 91 that has a concave portion 911 which opens to the top surface, and a plate-like lid 92 that is joined to the base 91 such that an opening of the concave portion 911 is closed. Such a package 9 has an accommodation space formed by closing the concave portion 911 by the lid 92, and thus the resonator element 2 is accommodated in an air-tight manner in the accommodation space. The resonator element 2 is fixed to the bottom surface of the concave portion 911 at the tip of the support arms 74 and 75 through conductive adhesives 11, 12, 13, and 14 in which an epoxy or acrylic resin is mixed with a conductive filler.

The accommodation space may be in a state of a pressure reduction (preferably vacuum) or may be sealed to have inert gas such as nitrogen, helium, or argon. Accordingly, the vibration characteristics of the resonator element 2 are improved.

A constituent material of the base 91 is not particularly limited, and various ceramics such as aluminum oxide can be used. In addition, a constituent material of the lid 92 is not particularly limited, and a material of which a linear expansion coefficient approximates that of the constituent material of the base 91 may be used. For example, in a case where the constituent material of the base 91 is the ceramics as described above, it is preferable that an alloy such as Kovar is used. The joining of the base 91 and the lid 92 is not particularly limited, for example, may be performed through an adhesive, or may be performed by seam welding or the like.

In addition, the connection terminals 951 and 961 are formed on the bottom surface of the concave portion 911 of the base 91. Though not illustrated, the first driving electrode 84 of the resonator element 2 extends to the tip of the support arm 74 and is electrically connected to the connection terminal 951 through the conductive adhesives 11 and 12 at the portion. Similarly, though not illustrated, the second driving electrode 85 of the resonator element 2 extends to the tip of the support arm 75 and is electrically connected to the connection terminal 961 through the conductive adhesives 13 and 14 at the portion.

In addition, the connection terminal 951 is electrically connected to an external terminal 953 formed on the bottom surface of the base 91 through a penetrating electrode 952 that penetrates through the base 91, and the connection terminal 961 is electrically connected to an external terminal 963 formed on the bottom surface of the base 91 through a penetrating electrode 962 that penetrates through the base 91.

As long as the connection terminals 951 and 961, the penetrating electrodes 952 and 962, and the external terminals 953 and 963 are each configured to have conductivity, the configuration is not particularly limited, and for example, can be formed of metal films in which films such as nickel (Ni), gold (Au), silver (Ag), and copper (Cu) are stacked on a metallized layer (ground layer) such as chromium (Cr), and tungsten (W).

### Manufacturing Method of Resonator Element

Next, the manufacturing method of the resonator element 2 (manufacturing method according to the invention) will be described with reference to FIGS. 14A to 15A. FIGS. 14A to 15A are cross sections corresponding to a cross section taken along line B-B in FIG. 1.

The manufacturing method of the resonator element 2 includes patterning of the quartz crystal substrate by using wet etching, a process of forming the quartz crystal substrate 3 having the proximal section 4, the vibration arms 5 and 6, and the support section 7, and forming the grooves 55, 56, 65, and 66 which form on the vibration arms 5 and 6 to satisfy the above relations. Hereinafter, the manufacturing method will be described in detail.

First, as illustrated in FIG. 14A, a Z-cut quartz crystal substrate 30 is prepared. The quartz crystal substrate 30 is a member to be the quartz crystal substrate 3 through the following processes. Next, as illustrated in FIG. 14B, a first mask M1 is formed on the top surface of the quartz crystal substrate 30 by using a photolithography method and simultaneously a second mask M2 is formed on the underside. The first and second masks M1 and M2 are masks that are formed to correspond to an external shape of the quartz crystal substrate 3. Next, the wet etching is performed on the quartz crystal substrate 30 through the first and second masks M1 and M2. Accordingly, as illustrated in FIG. 14C, the proximal section 4, the vibration arms 5 and 6 on which the grooves are not formed, and the support section 7 are integrally formed (here, the proximal section 4 and the support section 7 are not illustrated).

Next, as illustrated in FIG. 14D, a third mask M3 is formed on the top surface of the quartz crystal substrate 30 and simultaneously a fourth mask M4 is formed on the underside. The third mask M3 is a mask that is formed to correspond to the external shapes of the grooves 55 and 65 and the fourth mask M4 is a mask that is formed to correspond to the external shapes of the grooves 56 and 66.

Next, the wet etching is performed on the quartz crystal substrate 30 through the third and fourth masks M3 and M4 and thereby the grooves 55 and 56 are formed on the vibration arm 5 and the grooves 65 and 66 are formed on the vibration arm 6, as illustrated in FIG. 15A. Accordingly, the quartz crystal substrate 3 is obtained. Etching time is controlled in the wet etching such that the maximum depth t of the grooves 55, 56, 65, and 66 is a predetermined value. Accordingly, the quartz crystal substrate 3 (particularly the grooves 55, 56, 65, and 66) is formed through the wet etching, and thereby it is possible to form the grooves 55, 56, 65, and 66 in which a crystal surface of the quartz crystal appears, as using the simulation described above.

Next, as illustrated in FIG. 15B, a metal film 8 is formed on the front surface of the quartz crystal substrate 3. Next, as illustrated in FIG. 15C, for example, patterning is performed on the metal film 8 through a mask (not illustrated) and thereby the first and second driving electrodes 84 and 85 are formed. Then, the resonator element 2 is obtained. According to such a manufacturing method, it is possible to simply manufacture the resonator element 2 having good vibration characteristics.

### Second Embodiment

Next, a second embodiment of the resonator according to the invention will be described.

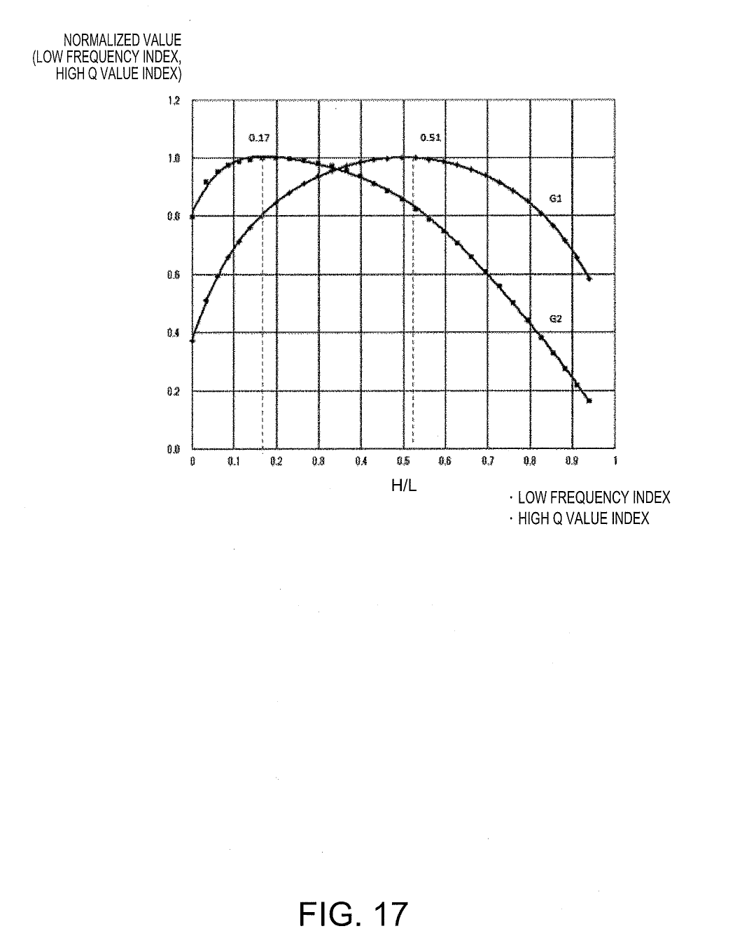

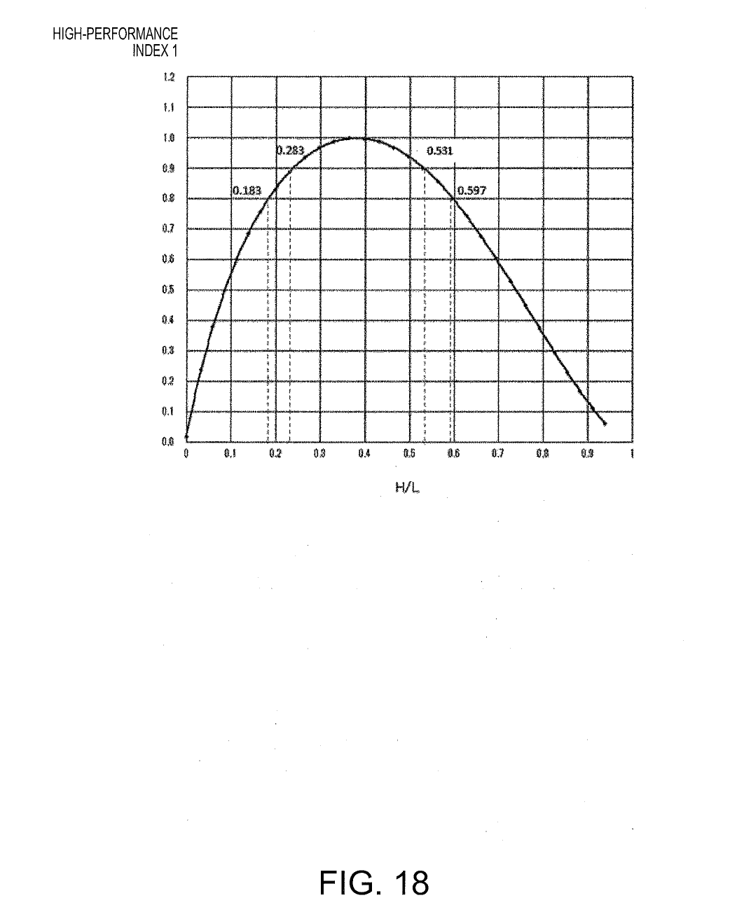

FIG. 17 is a graph illustrating a relationship between H/L and a normalized value according to the second embodiment. FIG. 18 is a graph illustrating a relationship between H/L and a high-performance index 1 according to the second embodiment.

Description of the resonator according to the second embodiment is focused on a difference from the first embodiment described above, and description of the same configurations is omitted.

The resonator according to the second embodiment of the invention is the same as in the first embodiment described above except that a relationship between the entire lengths of the vibration arms 5 and 6 and the lengths of the hammer-heads 59 and 69 is different.

Since the vibration arms 5 and 6 have the same configuration as each other, the vibration arm 5 is described representatively, and the description of the vibration arm 6 is omitted.

As illustrated in FIG. 1, in the resonator 1, when the length (length in the Y′ axis direction) of the vibration arm 5 in the longitudinal direction (extending direction) is L and the length (length in the Y′ axis direction) of the hammer-head 59 in the longitudinal direction is H, the vibration arm 5 satisfies a relationship of the following expression (33). Here, the hammer-head 59 is formed as a region of which the width is at least 1.5 times the width (length in the X axis direction) of the arm section 58.

0.183≦H/L≦0.597 (33)

As long as the relationship is satisfied, there is no particular limit, and further, it is preferable that a relationship of 0.238≦H/L≦0.531 is satisfied. Such a relationship is satisfied and thereby the resonator element 2 is obtained, in which both miniaturization and improvement of the Q value are achieved.

Hereinafter, effects obtained by satisfying the above expression (33) will be described with reference to FIGS. 17 and 18. Since the hammer-heads 59 and 69 have the same shape, the hammer-head 59 will be described representatively.

FIG. 17 illustrates a curved line G1 in which a relationship between the length H of the hammer-head 59 and a resonance frequency of the vibration arm 5 is indexed, and a curved line G2 in which a relationship between the length H of the hammer-head 59 and a Q value of the vibration arm 5 is indexed. The Q value illustrated in the curved line G2 is obtained taking only the thermoelastic loss into account. In addition, the ordinate of the curved line G1 is also referred to as “low-frequency index” and the ordinate of the curved line G2 is also referred to as “high Q value index”.

In addition, a simulation for obtaining the curved lines G1 and G2 was performed by using a single vibration arm 5. The vibration arm 5 used in the present simulation is configured of a quartz crystal Z sheet (rotation angle of 0°). In addition, the size of the vibration arm 5 is 1210 μm in the entire length, 100 μm in thickness, 98 μm in the width of the arm section 58, 172 μm in the width of the hammer-head 59, 45 μm in depth t of both of the grooves 55 and 56, and 6.5 μm in the width W of each of the banks 51a, 51b, 52b, and 52b. In such a vibration arm 5, the length H of the hammer-head 59 was changed and the simulation was conducted. The inventor confirms that, even when the size of the vibration arm 5 is changed, the same tendency is achieved as the simulation result which will be described later.

In FIG. 17, it is meant that the resonance frequency of the vibration arm 5 has the lowest value at a point (H/L=0.51) at which the curved line G1 has the normalized value (low frequency index)=1, and it is meant that the Q value of the vibration arm 5 has the highest value at a point (H/L=0.17) at which the curved line G2 has the normalized value (high Q value index)=1. Since the lower the resonance frequency of the vibration arm 5, the more the resonator element 2 can be miniaturized, H/L=0.51 (hereinafter, also referred to as “condition 1”), and thereby the resonator element 2 can be most miniaturized. In addition, since the higher the Q value, the less the thermoelastic loss and the better the vibration characteristics can be exhibited, H/L=0.17 (hereinafter, also referred to as “condition 2”), and thereby the resonator element 2 has the best vibration characteristics.

However, as understood in FIG. 17, when H/L=0.51, the high Q value index is not sufficiently high, and when H/L=0.17, the low frequency index is not sufficiently high. Thus, when only the condition 1 is satisfied, it is not possible to obtain good vibration characteristics. In contrast, when only the condition 2 is satisfied, it is not possible to achieve a sufficient miniaturization of the resonator element 2.

As an index for achieving both the miniaturization and the improvement of the vibration characteristics of the resonator element 2, “high-performance index 1” is set, and a relation between the high-performance index 1 and H/L is illustrated in FIG. 18. The “high-performance index 1” is represented by “low frequency index”×“high Q value index”×“correction value”. In addition, the high-performance index 1 is an index obtained when the maximum value thereof becomes 1. In addition, the “correction value” is used for adjusting the simulation performed by using the single vibration arm 5 to the resonator element 2 using the two vibration arms 5 and 6. Therefore, by using the correction value, it is possible to make the high-performance index 1 approximate physical properties of the resonator element 2.

Here, when the high-performance index 1 is 0.8 or higher, the resonator element 2 is obtained, in which both the miniaturization and the improvement of the vibration characteristics are sufficiently achieved. Therefore, in the resonator element 2, the length H of the hammer-head 59 is set such that a relationship of 0.183≦H/L≦0.597 is satisfied. That is, the resonator element 2 is configured to satisfy the above expression (33). In addition, within the range, it is preferable that a relationship of 0.238≦H/L≦0.531 is satisfied such that the high-performance index 1 becomes 0.9 or higher. Accordingly, the resonator element 2 is obtained, in which the miniaturization and the improvement of the vibration characteristics are further achieved.

In such a second embodiment, it is also possible to exhibit the same effects as in the first embodiment described above.

The second embodiment can also be applied to third, fourth, and fifth embodiments which will be described later.

### Third Embodiment

Next, the third embodiment of the resonator according to the invention will be described.

Description of the resonator according to the third embodiment is focused on a difference from the first embodiment described above, and description of the same configurations is omitted.

In a resonator 1 according to the third embodiment, the resonator element 2 has a fundamental vibration mode (X antiphase mode) in which the vibration arm 5 and the vibration arm 6 flexurally vibrate to sides opposite to each other in the X axis direction (second direction) to repeat approaching and separating from each other alternately.

The resonator element 2 satisfies a relationship of the following expression (17) when the resonance frequency of the fundamental vibration mode (X antiphase mode) is f0 and the resonance frequency of a vibration mode (spurious vibration mode) which is different from the fundamental vibration mode (X antiphase mode) is f1. Accordingly, an occurrence of combinations of the fundamental vibration mode and the spurious vibration mode is decreased and the resonator element 2 having good vibration characteristics (characteristics of a good vibration balance and thus of a small vibration leakage) is obtained.

|f0−f1|/f0≧0.124 (17)

To be more specific, since the fundamental vibration mode is set as a desired vibration mode, the resonator element 2 is designed such that the vibration leakage is to be small in a state of vibrating in the fundamental vibration mode. This is realized by connecting the two vibration arms 5 and 6 to the proximal section 4 as performed in the related art to offset vibration components which are displaced in directions opposite to each other in the proximal section 4. However, in a case of vibrating in the fundamental vibration mode in a state of combining with the spurious vibration mode, the energy is divided also to the spurious vibration mode, and a vibration mode of the spurious vibration mode occurs in the resonance frequency of the fundamental vibration mode. Therefore, in a state in which the vibration leakage in the spurious vibration mode is not designed to be difficult to occur, the vibration leaks from a held portion to the outside.

Hereinafter, this is demonstrated on the basis of examination results obtained by the inventor. In the present examination the resonator element 2 that is formed through patterning of the Z-cut quartz crystal sheet was used. In addition, the size of the quartz crystal substrate 3 of the resonator element 2 used is 1160 μm in length, 520 μm in width, 114 μm in thickness, that is, each thickness of the vibration arms 5 and 6, 930 μm in length of each of the vibration arms 5 and 6, and 60 μm in width of each of the arm sections 58 and 68 of the vibration arms 5 and 6. The inventor confirms that, even when each size is changed, there is substantially no difference from the result which will be shown later.

In the present examination, an example of the spurious vibration mode includes an “X equiphase mode” in which the vibration arms 5 and 6 flexurally vibrate to the same side in the X axis direction, and further the spurious vibration mode includes a “Z equiphase mode” in which the vibration arms 5 and 6 flexurally vibrate on the same side of the Z axis, a “Z antiphase mode” in which the vibration arms 5 and 6 flexurally vibrate to the opposite side of the Z axis, a “torsional equiphase mode” in which the vibration arms 5 and 6 are twisted about the Y′ axis in the same direction, a “torsional antiphase mode” in which the vibration arms 5 and 6 are twisted about the Y′ axis in the opposite directions, or the like, in addition to the X equiphase mode. The resonance frequencies of these spurious vibration modes other than the X equiphase mode are considered to be the same as the resonance frequency of the X equiphase mode in the present examination results, and thereby the combination between the fundamental vibration mode and the spurious vibration mode is caused to be weak, and thus it is possible to suppress an increase in the vibration leakage.

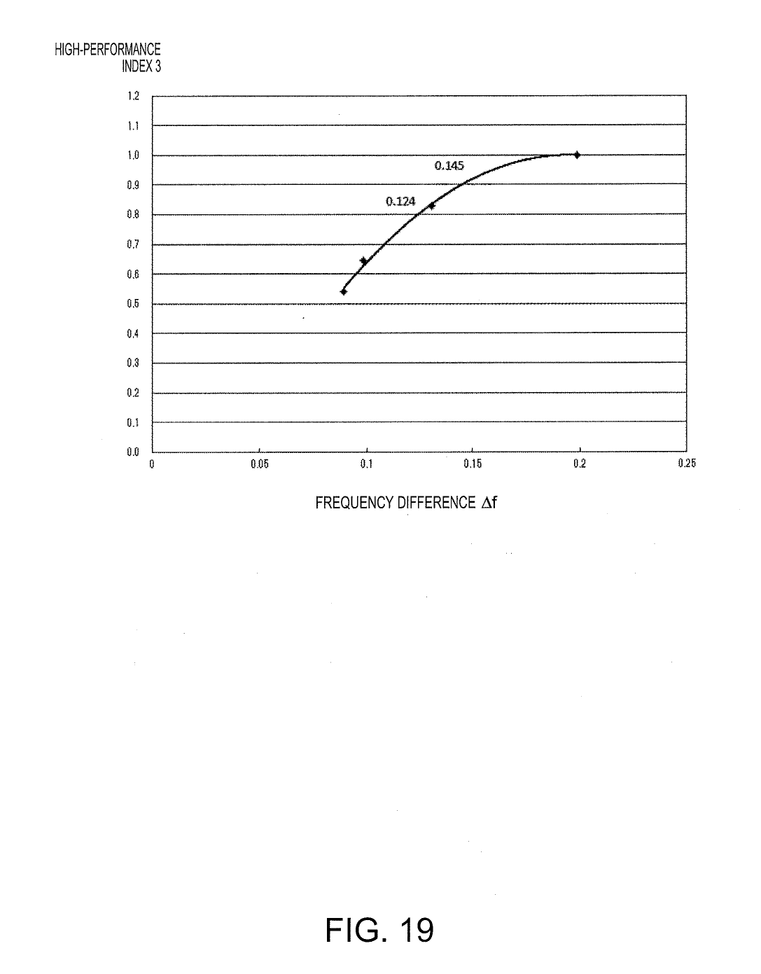

The following Table 2 shows a resonance frequency f0 of the fundamental vibration mode (X antiphase mode), a resonance frequency f1 of the X equiphase mode, a frequency difference Δf, and a high-performance index 3 of four samples SAM1 to SAM4. Δf is represented by the following expression (18) and the high-performance index 3 is an index obtained when the highest Q value of all of the samples becomes 1. Thus, it means that the closer the high-performance index 3 is to 1, the higher the Q value. In addition, a graph obtained by plotting the high-performance index 3 of the samples SAM1 to SAM4 is illustrated in FIG. 19.

Δf=|f0−f1|/f0 (18)

TABLE 2

| | X | X | | | |
|---|---|---|---|---|---|
| | equiphase | antiphase | | | High- |
| | mode | mode | | | performance |
| | [kHz] | [kHz] | \|Δf\| | Q | index 3 |
| SAM1 | 29.797 | 32.720 | 8.9% | 7.309 | 0.54 |
| SAM2 | 29.498 | 32.724 | 9.9% | 8.709 | 0.65 |
| SAM3 | 28.444 | 32.713 | 13.0% | 11.183 | 0.83 |
| SAM4 | 26.419 | 32.972 | 19.9% | 13.500 | 1.00 |

Here, when the high-performance index 3 is 0.8 or higher, the resonator element 2 having a high Q value (having good vibration characteristics) is obtained. When the high-performance index 3 is 0.9 or higher, the resonator element 2 having a higher Q value is obtained. When the high-performance index 3 is 1, the resonator element 2 having a further higher Q value is obtained. A quadratic expression (approximation expression) obtained by connecting the high-performance indexes 3 of the samples is represented by the following expression (19). Therefore, it is understood from the expression (19), when the high-performance index 3 is 0.8, Δf=0.124, when the high-performance index 3 is 0.9, Δf=0.145, and when the high-performance index is 1, Δf=0.2.

−4.016×10×Δf²+1.564×10×Δf−5.238×10⁻¹ (19)

Thus, it is demonstrated that the above expression (17) is satisfied, and thereby the resonator element 2 having good vibration characteristics is obtained, the following expression (20) is satisfied, and thereby the resonator element 2 having better vibration characteristics is obtained, and the following expression (21) is satisfied, and thereby the resonator element 2 having much better vibration characteristics is obtained.

|f0−f1|/f0≧0.145 (20)

|f0−f1|/f0≧0.2 (21)

In such a third embodiment, it is also possible to exhibit the same effects as in the first embodiment described above.

The third embodiment can also be applied to the fourth and fifth embodiments which will be described later.

### Fourth Embodiment

Next, the fourth embodiment of the resonator according to the invention will be described.

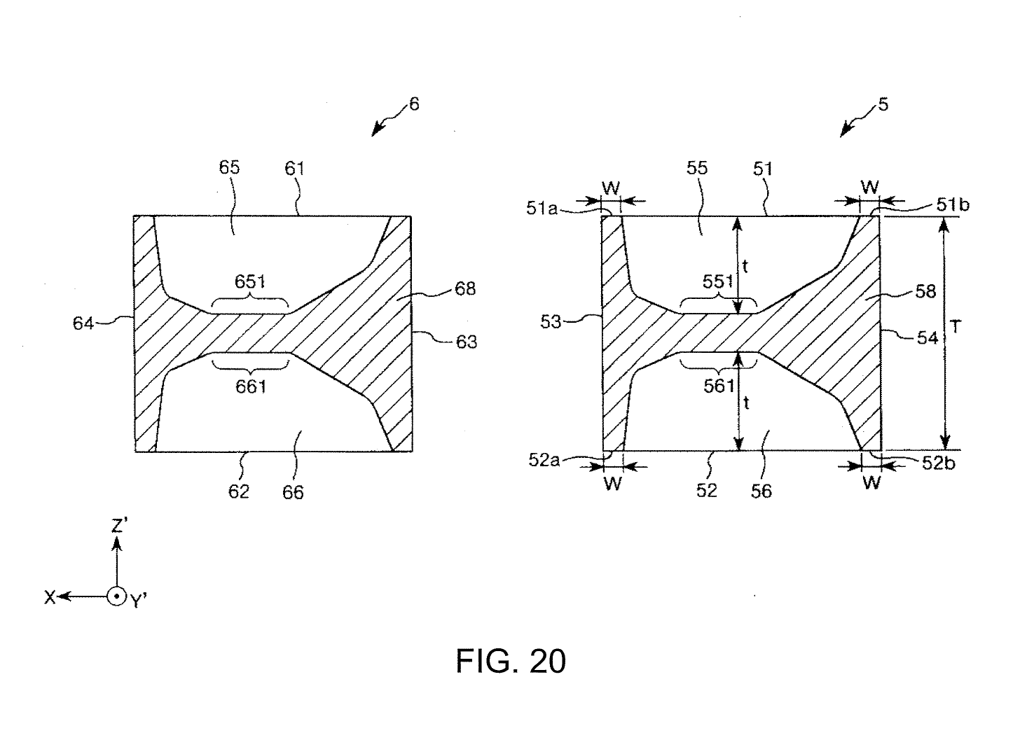

FIG. 20 is a cross-sectional view (view corresponding to FIG. 6) of the resonator element included in the resonator according to the fourth embodiment of the invention.

Hereinafter, description of the resonator according to the fourth embodiment is focused on a difference from the first embodiment described above, and description of the same configurations is omitted.

The resonator according to the fourth embodiment of the invention is the same as in the first embodiment described above except that a configuration of the resonator element is different.

As illustrated in FIG. 20, the grooves 55, 56, 65, and 66 have the bottom surfaces (flat surfaces) 551, 561, 651, and 661 which have a uniform depth, respectively. Accordingly, since a path through which heat produced due to the flexural vibration flows has to pass for a longer time through a narrow region compared to a resonator element including a groove having a bottom surface with a non-uniform depth, it is possible to decrease the thermoelastic loss, and to obtain a high Q value.

In such a fourth embodiment, it is also possible to exhibit the same effects as in the first embodiment described above.

The fourth embodiment can also be applied to the fifth embodiments which will be described later.

### Fifth Embodiment

Next, the fifth embodiment of the resonator according to the invention will be described.

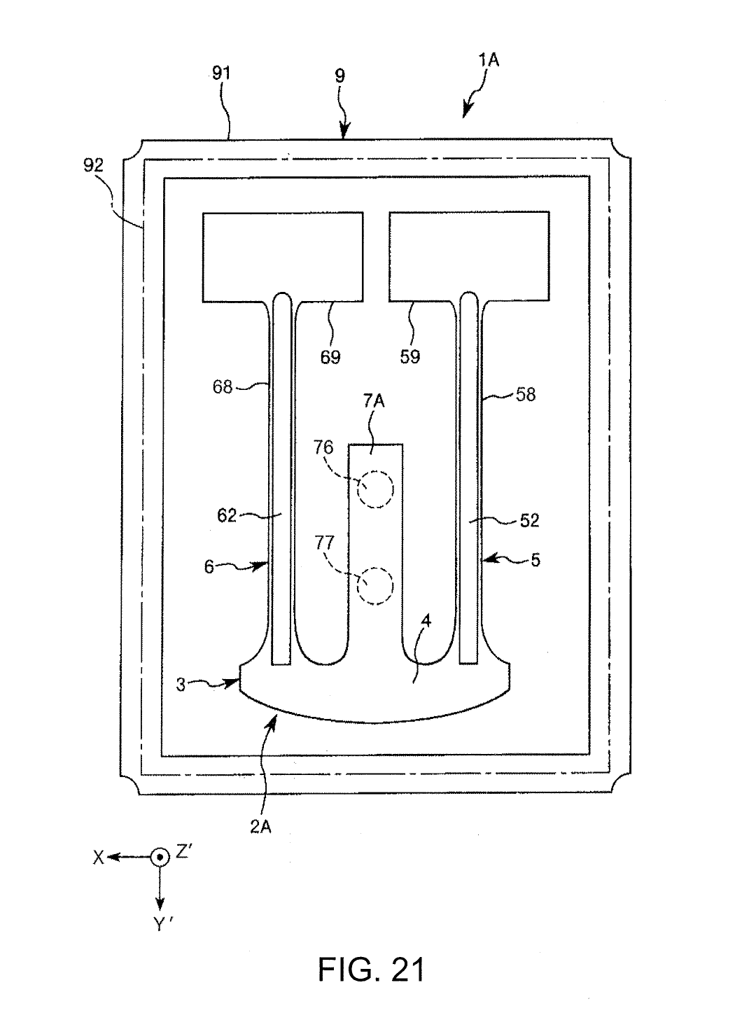

FIG. 21 is a plan view of the resonator according to the fifth embodiment of the invention.

Hereinafter, description of the resonator according to the fifth embodiment is focused on a difference from the first embodiment described above, and description of the same configurations is omitted.

The resonator according to the fifth embodiment of the invention is the same as in the first embodiment described above except that a configuration of the resonator element is different.

As illustrated in FIG. 21, a resonator element 2A of a resonator 1A includes the proximal section 4, the vibration arms 5 and 6 that extend from the proximal section 4 in the −Y′ axis direction, and a support arm 7A that extends from the proximal section 4 in the −Y′ axis direction. Such a resonator 1A is attached to the package 9 on fixation portions 76 and 77 of the support arm 7A through an adhesive. The vibration arms 5 and 6 include arm sections 58 and 68 and the hammer-heads 59 and 69.

In such a fifth embodiment, it is also possible to exhibit the same effects as in the first embodiment described above.

### 2. Oscillator

Next, an oscillator (oscillator according to the invention) to which the resonator element according to the invention is applied will be described.

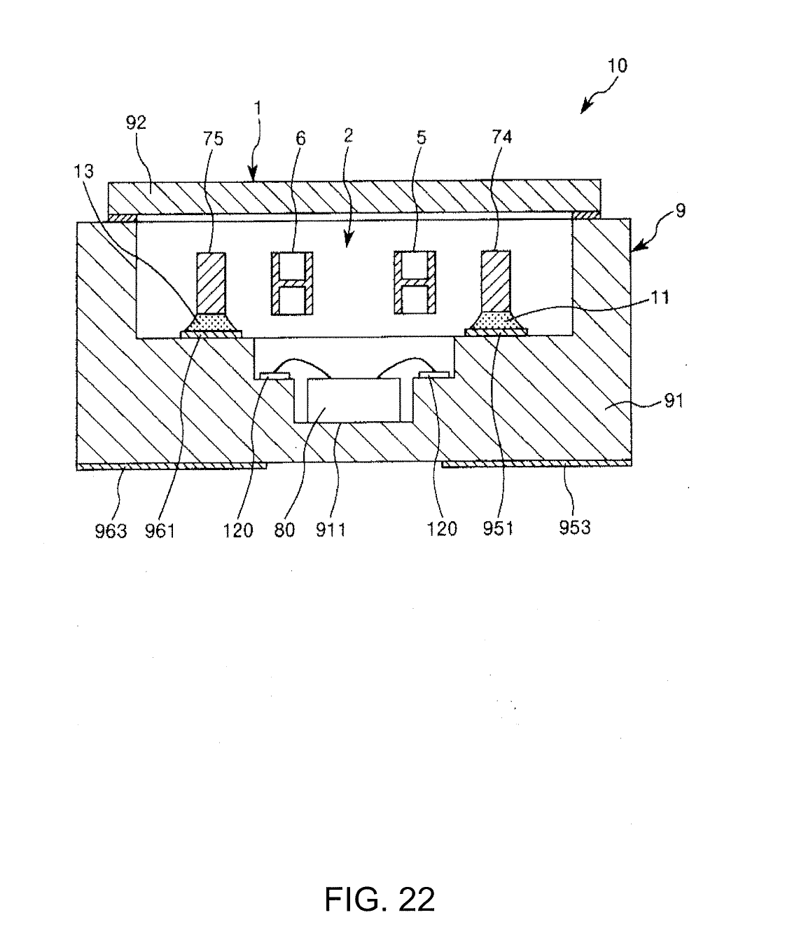

FIG. 22 is a cross-sectional view illustrating an embodiment of the oscillator according to the invention.

An oscillator 10 illustrated in FIG. 22 includes the resonator 1 and an IC chip 80 for driving the resonator element 2. Hereinafter description of the oscillator 10 is focused on a difference from the resonator described above, and description of the same configurations is omitted.

As illustrated in FIG. 22, the IC chip 80 is fixed to the concave portion 911 of the base 91 in the oscillator 10. The IC chip 80 is electrically connected to a plurality of internal terminals 120 formed on the bottom surface of the concave portion 911. Among the plurality of internal terminals 120, some are connected to the connection terminals 951 and 961 and some are connected to the external terminals 953 and 963. The IC chip 80 has an oscillation circuit (circuit) for controlling the driving of the resonator element 2. When the IC chip 80 causes the resonator element 2 to drive, it is possible to extract a signal of a predetermined frequency.

### 3. Electronic Apparatus

Next, an electronic apparatus (electronic apparatus according to the invention) to which the resonator element according to the invention is applied will be described.

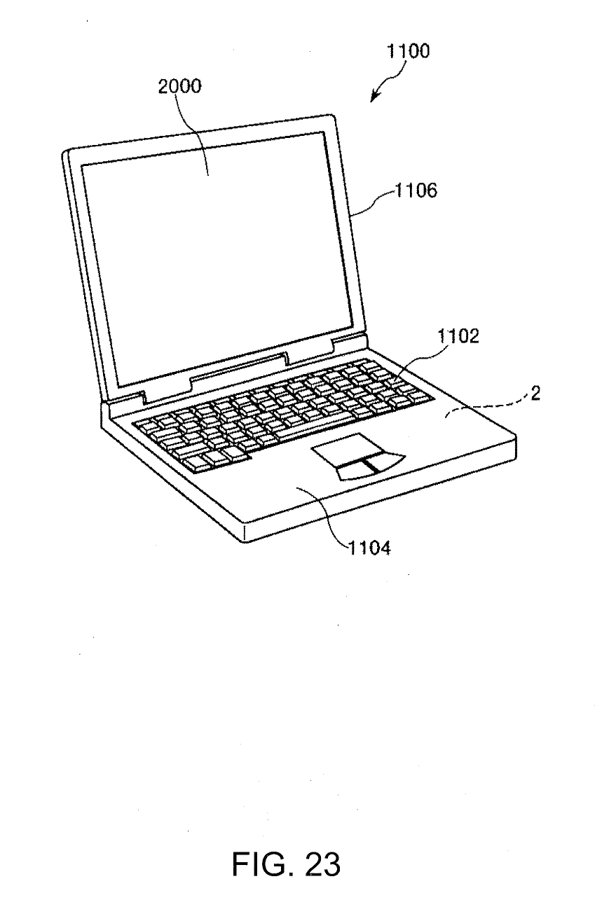

FIG. 23 is a perspective view illustrating a configuration of a mobile-type (or notebook-type) personal computer to which the electronic apparatus according to the invention is applied. In FIG. 23, a personal computer 1100 is configured to have a main body section 1104 that includes a keyboard 1102, and a display unit 1106 that includes a display section 100, and the display unit 1106 is rotatably supported with respect to the main body section 1104 through a hinge structure section. The personal computer 1100 is equipped with the resonator 1 that functions as a filter, a resonator, a reference clock or the like.

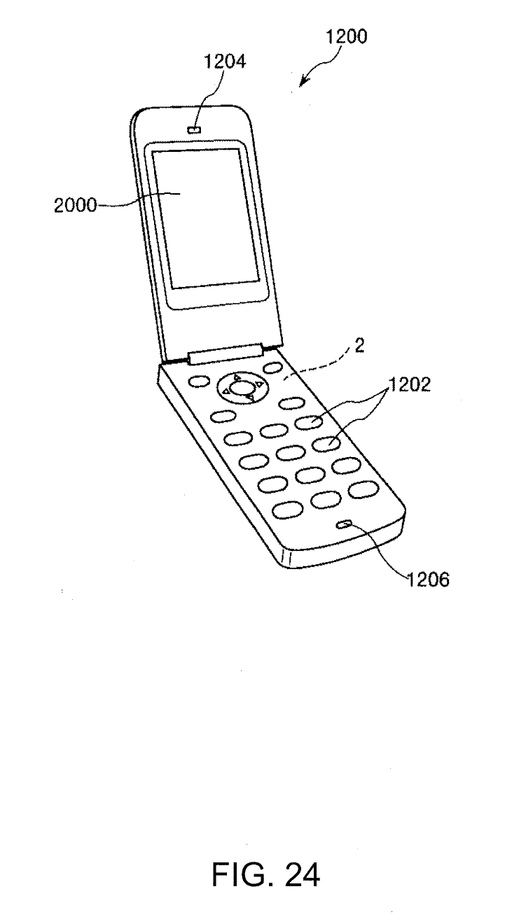

FIG. 24 is a perspective view illustrating a configuration of a mobile phone (including a PHS) to which the electronic apparatus according to the invention is applied. In FIG. 24, a mobile phone 1200 includes a plurality of operation buttons 1202, an earpiece 1204, and a mouthpiece 1206. A display section 100 is disposed between the operation buttons 1202 and the earpiece 1204. Such a mobile phone 1200 is equipped with the resonator element 2 that functions as a filter, a resonator, or the like.

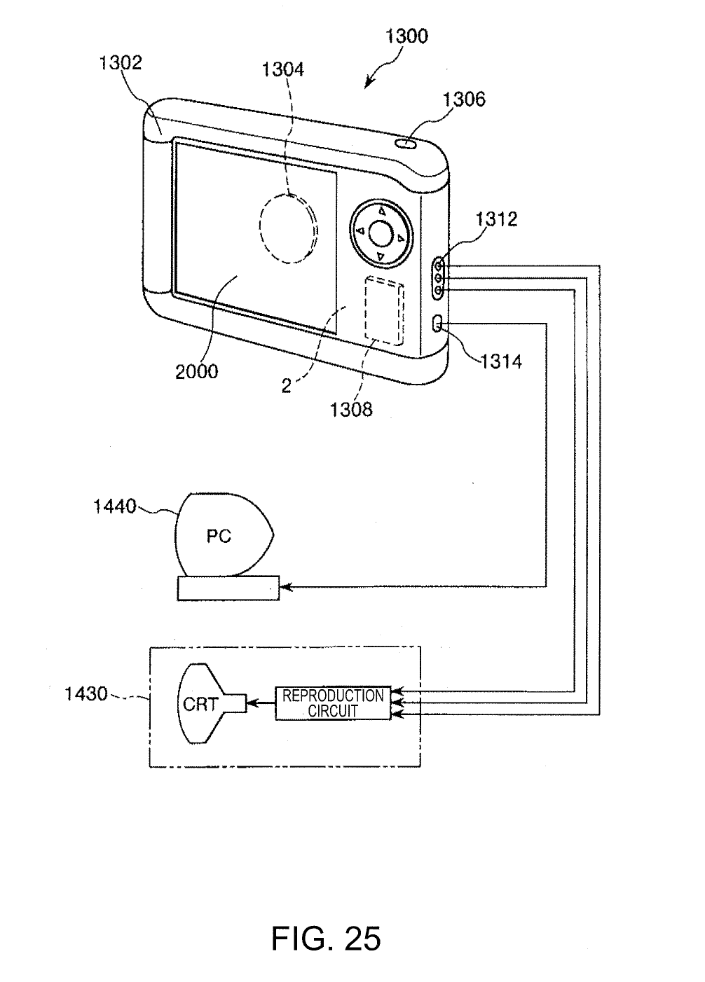

FIG. 25 is a perspective view illustrating a configuration of a digital still camera to which the electronic apparatus of the invention is applied. In FIG. 25, connection to an external apparatus is illustrated in a simplified manner. Here, a camera in the related art exposes a silver salt photographic film to an optical image of a subject. In contrast, a digital still camera 1300 performs photoelectric conversion of an optical image of a subject, using an imaging device, such as a charge coupled device (CCD), and generates an imaging signal (image signal).

A display section is provided on the back surface of a case (body) 1302 in the digital still camera 1300, and has a configuration in which a display is performed on the basis of an imaging signal by the CCD, and the display section functions as a finder to display the subject as an electronic image. In addition, a photosensitive unit 1304 that includes an optical lens (imaging optical system), a CCD, or the like is provided on the front surface side (rear surface side in FIG. 25) of the case 1302.

When a photographer checks an image of a subject displayed on the display section, and presses a shutter button 1306, an imaging signal of the CCD at the time point is transmitted to and stored in a memory 1308. In addition, in the digital still camera 1300, a video signal output terminal 1312 and an input/output terminal 1314 for data communication are provided on the side surface of the case 1302. As illustrated in FIG. 25, a television monitor 1430 is connected to the video signal output terminal 1312, and a personal computer 1440 is connected to the input/output terminal 1314 for data communication, as necessary. Further, the imaging signal stored in the memory 1308 is configured to be output to the television monitor 1430 or to the personal computer 1440 by a predetermined operation. Such a digital still camera 1300 is equipped with the resonator 1 that functions as a filter, a resonator, or the like.

In addition to applications of the electronic apparatus that includes the resonator element according to the invention to the personal computer (mobile personal computer) in FIG. 23, to the mobile phone in FIG. 24, and to the digital still camera in FIG. 25, the electronic apparatus can be applied to an ink jet discharge apparatus (for example, ink jet printer), a laptop personal computer, a TV, a video camera, a video tape recorder, a car navigation device, a pager, an electronic organizer (including a communicating function), an electronic dictionary, a calculator, an electronic game device, a word processor, a workstation, a TV phone, a security television monitor, electronic binoculars, a POS terminal, a medical apparatus (for example, an electronic thermometer, a sphygmomanometer, a blood glucose meter, an electrocardiogram measuring device, an ultrasonic diagnostic apparatus, or an electronic endoscope), a fishfinder, various measurement apparatuses, meters (for example, meters in a vehicle, an aircraft, or a ship), or a flight simulator.

### 4. Mobile Object

Next, a mobile object (mobile object according to the invention) to which the resonator element according to the invention is applied will be described.

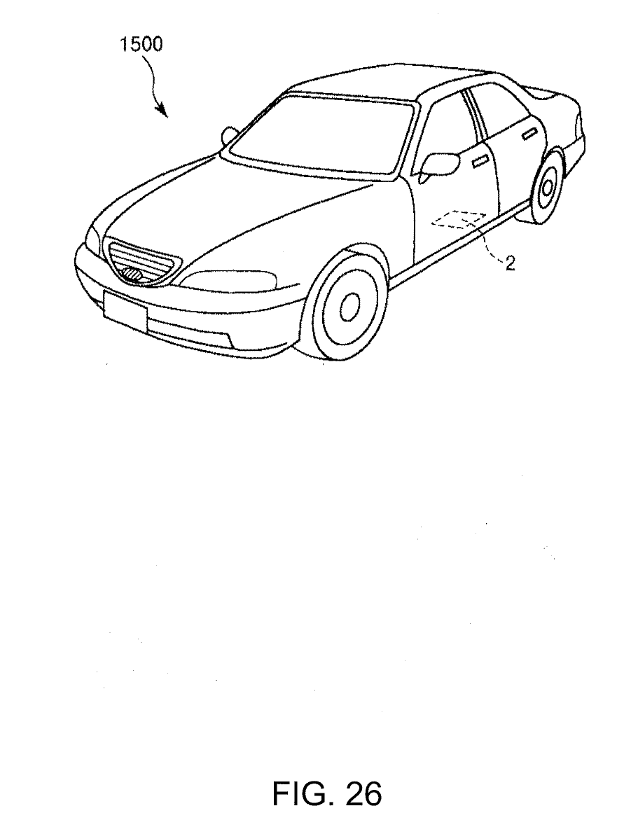

FIG. 26 is a perspective view illustrating a configuration of an automobile to which the mobile object according to the invention is applied. The resonator element 2 according to the invention is mounted on an automobile 1500. The resonator element 2 can be widely applied to an electronic control unit (ECU), such as keyless entry, an immobilizer, a car navigation system, a car air conditioner, an anti-lock brake system (ABS), an airbag, a tire pressure monitoring system (TPMS), an engine control, a battery monitor of a hybrid car or an electric car, or a vehicle body posture control system.

The resonator element, the resonator, the oscillator, the electronic apparatus, and the mobile object according to the invention are described in accordance with the embodiments illustrated in drawings, but the invention is not limited thereto. The configuration of each component can be substituted with another component having an arbitrary configuration which has the same function. In addition, another arbitrary component may be added to the invention. In addition, the embodiments may be appropriately combined.

In addition, the resonator element can be applied to, for example, a gyro sensor or the like.

What is claimed is:

1. A resonator element comprising:
a proximal section; and
a vibration arm which extends from the proximal section in a plan view and in which grooves are provided on a first main surface and on a second main surface thereof which are on a front side and on a rear side of the vibration arm,
the vibration arm including:
a weight section; and
an arm section that is disposed between the proximal section and the weight section in a plan view,
when a thickness of the vibration arm is T,
a width of the first main surface between an outer edge of the vibration arm and a corresponding one of the grooves in a plan view along a direction orthogonal to an extending direction of the first main surface is W,
a sum of depths of the grooves is ta, and
ta/T is η,
a region that satisfies
4.236×10×η²−8.473×10×η+4.414×10 [μm]≦W [μm]≦−3.367×10×η²+7.112×10×η−2.352×10 [μm], and
0.75≦η<1.00
is at least a part of the vibration arm in the extending direction, and
when a length of the vibration arm along the extending direction is L, and
a length of the weight section along the extending direction is H,
a relationship of
0.012<H/L<0.30 is satisfied.

2. A resonator element comprising:
a proximal section; and
a vibration arm which extends from the proximal section in a plan view and in which grooves are provided on a first main surface and on a second main surface thereof which are on a front side and on a rear side of the vibration arm,
the vibration arm including:
a weight section; and
an arm section that is disposed between the proximal section and the weight section in a plan view,
when a thickness of the vibration arm is T,
a width of the first main surface between an outer edge of the vibration arm and a corresponding one of the grooves in a plan view along a direction orthogonal to an extending direction of the first main surface is W,
a sum of depths of the grooves is ta, and
ta/T is η,
a region that satisfies
4.236×10×η²−8.473×10×η+4.414×10 [μm]≦W [μm]≦−3.367×10×η²+7.112×10×η−2.352×10 [μm], and
0.75≦η<1.00
is at least a part of the vibration arm in the extending direction, and
when a length of the vibration arm along the extending direction is L, and
a length of the weight section along the extending direction is H,
a relationship of
0.183≦H/L≦0.597 is satisfied.

3. The resonator element according to claim 1,
wherein the thickness of the vibration arm is 110 μm to 150 μm.

4. The resonator element according to claim 1,
wherein a pair of the vibration arms are provided,
wherein the pair of vibration arms each have a fundamental vibration mode to flexurally vibrate along the orthogonal direction such that the pair of vibration arms repeats approaching and separating from each other alternately, and
wherein, when a resonance frequency of the fundamental vibration mode is f0, and
a resonance frequency of a vibration mode different from the fundamental vibration mode is f1,
a relationship of

|f0−f1|/f0≧0.124 is satisfied.

5. The resonator element according to claim 1,
the grooves have a bottom surface with a uniform depth.

6. The resonator element according to claim 1,
the grooves have a bottom surface with a non-uniform depth.

7. A resonator comprising:
the resonator element according to claim 1; and
a package in which the resonator element is accommodated.

8. A resonator comprising:
the resonator element according to claim 2; and
a package in which the resonator element is accommodated.

9. An oscillator comprising:
the resonator element according to claim 1; and
an oscillation circuit that is connected electrically to the resonator element.

10. An oscillator comprising:
the resonator element according to claim 2; and
an oscillation circuit that is connected electrically to the resonator element.

11. An electronic apparatus comprising:
the resonator element according to claim 1.

12. An electronic apparatus comprising:
the resonator element according to claim 2.

13. A mobile object comprising:
the resonator element according to claim 1.

14. A mobile object comprising:
the resonator element according to claim 2.

15. A resonator element comprising:
a proximal section; and
a vibration arm which extends from the proximal section, the vibration arm having grooves on a first main surface and on a second main surface thereof, the grooves being on a front side and on a rear side of the vibration arm,
the vibration arm including:
a weight section; and
an arm section that is disposed between the proximal section and the weight section,
when a length of the vibration arm along the extending direction is L, and
a length of the weight section along the extending direction is H,
a relationship of
0.183<H/L<0.597 is satisfied.

16. The resonator element according to claim 1, where a relationship of 0.012<H/L<0.30 is satisfied.

17. The resonator element according to claim 15,
wherein a pair of the vibration arms are provided,
wherein the pair of vibration arms each have a fundamental vibration mode to flexurally vibrate along the orthogonal direction such that the pair of vibration arms repeats approaching and separating from each other alternately, and
wherein, when a resonance frequency of the fundamental vibration mode is f0, and
a resonance frequency of a vibration mode different from the fundamental vibration mode is f1,
a relationship of

|f0−f1|/f0≧0.124 is satisfied.

18. The resonator element according to claim 15,
the grooves have a bottom surface with a uniform depth.

19. The resonator element according to claim 15,
the grooves have a bottom surface with a non-uniform depth.

20. A resonator comprising:
the resonator element according to claim 15; and
a package in which the resonator element is accommodated.
